(19) United States
(12) Patent Application Publication
(10) Pub. No.: US 2012/0107970 A1
(43) Pub. Date: May 3, 2012

(54) MANUFACTURING METHOD OF SEMICONDUCTOR DEVICE

(75) Inventor: Seje TAKAKI, Kanagawa (JP)

(73) Assignee: RENESAS ELECTRONICS CORPORATION

(21) Appl. No.: 13/286,201

(22) Filed: Oct. 31, 2011

(30) Foreign Application Priority Data
Nov. 1, 2010 (JP) 2010-245160

(51) Int. Cl. H01L 21/66

(52) U.S. Cl. 438/16; 257/E21.53

(57) ABSTRACT

A manufacturing method of a semiconductor device is provided to improve the reliability of electrical coupling of the semiconductor device. The manufacturing method includes the steps of (a) laminating a main conductive film (base film) and a stopper insulating film (film to be measured) above the main conductive film, over a main surface of a semiconductor substrate, (b) forming an opening in the stopper film, (c) applying an electron beam (excitation beam) to the opening to emit characteristic X-rays, and (d) detecting the characteristic X-rays to determine the presence or absence, or thickness of the stopper insulating film at the bottom of the opening based on detection result of the characteristic X-rays. In the step (d), the presence or absence, or thickness of the stopper film is determined by a ratio of element components contained in the characteristic X-rays.

### CROSS-REFERENCE TO RELATED APPLICATIONS

The disclosure of Japanese Patent Application No. 2010-245160 filed on Nov. 1, 2010 including the specification, drawings and abstract is incorporated herein by reference in its entirety.

### BACKGROUND

The present invention relates to manufacturing techniques for semiconductor devices, and more particularly, to a technique effectively applied to a process for checking the presence or absence or the thickness of a remaining film after forming an opening in a laminated film formed over a semiconductor substrate.

Japanese Unexamined Patent Publication No. 2005-98923 (Patent Document 1) discloses a thickness measuring method for measuring the thickness of a film to be measured which involves measuring the amount of secondary electrons emitted from the film to be measured by applying an electron beam to the film to be measured.

Japanese Unexamined Patent Publication No. 2008-34475 (Patent Document 2) discloses a method for measuring the thickness of a remaining film at the bottom of a contact hole. As described in Patent Document 2, the thickness or resistance of the remaining film can be estimated by measuring a potential contrast of a secondary electron image of an object of interest to be checked by irradiating the contact hole with an electron beam.

### RELATED ART DOCUMENTS

### Patent Documents

[Patent Document 1]
Japanese Unexamined Patent Publication No. 2005-98923
[Patent Document 2]
Japanese Unexamined Patent Publication No. 2008-34475

### SUMMARY

A manufacturing procedure of a semiconductor device includes a step (hereinafter referring to as a wiring layer lamination step) which involves laminating wiring layers over a main surface of a semiconductor substrate after forming a semiconductor element over the main surface, and electrically coupling the semiconductor element to a plurality of electrodes (pads) formed in the uppermost wiring layer. In the wiring layer lamination step, an insulating film is formed over a base film (main surface of the semiconductor substrate or an upper surface of the lower wiring layer), and an opening, such as a trench (wiring trench) or hole (contact hole), is formed in the insulating film. And, the opening is filled with a conductive film to thereby form the wiring layer for electrically coupling an upper layer to a lower layer. From a viewpoint of ensuring the reliability of electrical coupling of the semiconductor device, it is important to form the opening that surely penetrates the insulating film. This is because the opening not penetrating the insulating film causes the failure of electrical coupling (open failure).

The opening is formed, for example, by forming a resist film with a resist pattern formed over the insulating film and by performing etching using the resist film as a mask. In this case, a step of removing (ashing step) or cleaning the resist film is necessary, but for the purpose of protecting the lower wiring layer, the following method is effective in the ashing or cleaning step. That is, this method is effective in that the ashing step or cleaning step is performed while a part of the insulating film remains thinly at the bottom of the opening, and then the remaining thin film (remaining film) is removed. In order to use such a method, it is very important to maintain the thin remaining film without completely removing the remaining film during an etching step. This is because the lower wiring layer fails to be protected when the remaining film is completely removed before the ashing step or cleaning step, which causes the failures (the failure of penetration). That is, the formation of the opening in the insulating film needs a technique for controlling the depth of the opening.

Accordingly, the inventors in the present application have studied a technique for checking the presence or absence or the thickness of the remaining film as technical means for controlling the depth of the opening formed in an insulating film, and then have found out the following problems.

That is, as described in the above Patent Document 1 and Patent Document 2, in a case where the amount of secondary electrons emitted from the film to be measured, or the contrast of potential of the secondary electron image is measured by applying the electron beam to the film to be measured, the accuracy of measurement of the remaining film is possibly reduced, or the measurement of the remaining film cannot be performed.

For example, when an aspect ratio of the opening is large, the secondary electrons emitted from the film to be measured or the base film is easily absorbed in the wiring trench or sidewall of the contact hole. As a result, the amount of secondary electrons detected is decreased, which reduces the accuracy of measurement or makes the measurement impossible. The amount of detected secondary electrons is apt to be affected by noise due to a pattern of the part around the opening, which causes the reduction in accuracy of the measurement. For example, when the film to be measured and the base film each are formed of materials with the similar properties of emission of secondary electrons (for example, both being formed of metal films), a difference in amount of emission of the secondary electrons between the film to be measured and the base film is not obvious, which would reduce the accuracy of measurement or would make the measurement impossible.

When it takes much time to check the presence or absence or the thickness of the remaining film, a feedback time to a manufacturing process is increased, which reduces the efficiency of manufacturing. Thus, in order to suppress the reduction in manufacturing efficiency, it is necessary to shorten the time to check the presence or absence or the thickness of the remaining film.

The present invention has been made in view of the forgoing problems, and it is an object of the present invention to provide a technique for improving the reliability of electrical coupling of a semiconductor device. It is another object of the invention to provide a technique for efficiently checking the presence or absence or the thickness of a remaining film.

The above and other objects and the novel features of the invention will become apparent from the description of the present specification and the accompanying drawings.

The outline of representative aspects of the invention disclosed in the present application will be briefly described as follows.

That is, a manufacturing method of a semiconductor device according to one aspect of the invention in the present application includes the steps of: (a) laminating a base film and a film to be measured above the base film, over a main surface of a semiconductor substrate; and (b) forming an opening in the film to be measured. The method includes the steps of: (c) applying an excitation beam to the opening to emit characteristic X-rays; and (d) detecting the characteristic X-rays to thereby determine the presence or absence or the thickness of the film to be measured at the bottom of the opening based on the result of detection of the characteristic X-rays. In the step (d), the presence or absence, or the thickness of the film to be measured is determined by a ratio of components contained in the characteristic X-rays.

Effects obtained from the representative aspects of the invention disclosed in the present application will be briefly described as follows.

That is, according to one aspect of the invention in the present application, the reliability of electrical coupling of the semiconductor device can be improved. Further, the presence or absence or the thickness of the remaining film can be effectively checked.

### BRIEF DESCRIPTION OF THE DRAWINGS

FIG. 1 is a plan view showing one example of an entire structure of a semiconductor device according to one embodiment of the invention;

FIG. 2 is an enlarged cross-sectional view showing one example of a sectional structure of the semiconductor device shown in FIG. 1;

FIG. 3 is an explanatory diagram showing the outline of the flow of a manufacturing process of the semiconductor device shown in FIGS. 1 and 2;

FIG. 4 is a plan view of a semiconductor substrate prepared in a semiconductor substrate preparation step shown in FIG. 3;

FIG. 5 is an explanatory diagram showing a process flow of a wiring layer lamination step shown in FIG. 3;

FIG. 6 is an enlarged cross-sectional view showing the state of formation of a base layer of the fourth wiring layer shown in FIG. 2;

FIG. 7 is an enlarged cross-sectional view showing the state of an etching stopper film deposited on the upper surface of the wiring layer shown in FIG. 6;

FIG. 8 is an enlarged cross-sectional view showing the state of a main insulating film deposited on the etching stopper film shown in FIG. 7;

FIG. 9 is an enlarged cross-sectional view showing the state of a mask disposed on the main insulating film shown in FIG. 8 so as to form a contact hole;

FIG. 10 is an enlarged cross-sectional view showing the state of the contact hole formed in the insulating film shown in FIG. 9;

FIG. 11 is an enlarged cross-sectional view showing the state of a wiring trench formed by disposing another mask for forming a wiring trench after removing the mask shown in FIG. 10;

FIG. 12 is an enlarged cross-sectional view showing the state of removal of the remaining film under the contact hole after removing the mask shown in FIG. 11;

FIG. 13 is an enlarged cross-sectional view showing the state of a barrier conductive film deposited in an opening after removing the remaining film at the bottom of the opening shown in FIG. 12;

FIG. 14 is an enlarged cross-sectional view showing the state of a main conductive film embedded in the opening shown in FIG. 13;

FIG. 15 is an enlarged cross-sectional view showing the state of the removal of a part of the conductive film on the upper surface of the insulating film by performing a planarization process on the upper surface of the insulating film shown in FIG. 14;

FIG. 16 is an explanatory diagram exemplarily showing a remaining film checking step shown in FIG. 5;

FIG. 17 is an explanatory diagram showing the relationship between the presence or absence of the remaining film and the ratio of components (Cu/Si) when changing the intensity (acceleration voltage) of an electron beam applied to the opening shown in FIG. 16;

FIG. 18 is an explanatory diagram showing the relationship between the thickness of the remaining film and the ratio of components (Cu/Si) at each intensity (acceleration voltage) of the electron beam applied to the opening shown in FIG. 16;

FIG. 19 is an explanatory diagram showing the outline of the structure of a remaining film checking device;

FIG. 20 is a plan view showing an example of positions of openings for checking the remaining film in the remaining film checking step shown in FIG. 5;

FIG. 21 is an enlarged plan view of a part “A” shown in FIG. 20;

FIG. 22 is an explanatory diagram showing a process flow of a wiring layer lamination step shown in FIG. 3;

FIG. 23 is an enlarged cross-sectional view showing the state of completion of a contact hole penetration step shown in FIG. 22;

FIG. 24 is an explanatory diagram exemplarily showing the state of a part “B” shown in FIG. 23 after the remaining film checking step;

FIG. 25 is an explanatory diagram showing the relationship between the presence or absence of the remaining film and a ratio of components (Co/Si) when changing the intensity (acceleration voltage) of the electron beam applied to the opening shown in FIG. 24;

FIG. 26 is an explanatory diagram exemplarily showing a modified example of the remaining film checking step shown in FIG. 16;

FIG. 27 is an explanatory diagram showing the relationship between the presence or absence of the remaining film and a ratio of components (Ti/Al) when changing the intensity (acceleration voltage) of the electron beam applied to the opening shown in FIG. 26;

FIG. 28 is an explanatory diagram exemplarily showing a remaining film checking step as a first comparative example; and

FIG. 29 is an explanatory diagram exemplarily showing a remaining film checking step as a second comparative example.

### DETAILED DESCRIPTION

### (Explanation of Description Format in Present Application)

The following preferred embodiments in this patent application may be described below by being divided into a plurality of sections or the like for convenience, if necessary, which are not independent from each other except when specified otherwise. Regardless of the order of the description, each section corresponds to each part of a single example, or one of the sections is a detailed part of the other, a part or all of a modified example, or the like. A repeated description of the same part will be omitted below in principle. Each component of the embodiments is not essential, unless otherwise specified, except when definitely limited to the specific number in theory, and unless otherwise specified from the context. In each drawing of the embodiments, the same or like parts are designated by the same or similar reference characters or numerals, and a description thereof will not be repeated in principle. In the accompanying drawings, when a cross-sectional part becomes complicated, or when a part of interest is obviously distinguished from a void, hatching or the like is omitted in the cross-sectional view. In this context, a background outline of even a hole closed in a planar manner may be often omitted as is evident from the explanation or the like. Further, hatching or dot patterns may be provided even in a diagram which is not the cross-sectional view, in order to clearly show that the part of interest in the drawing is not the cavity, or to clearly show the boundary between regions.

### <Outline of Semiconductor Device>

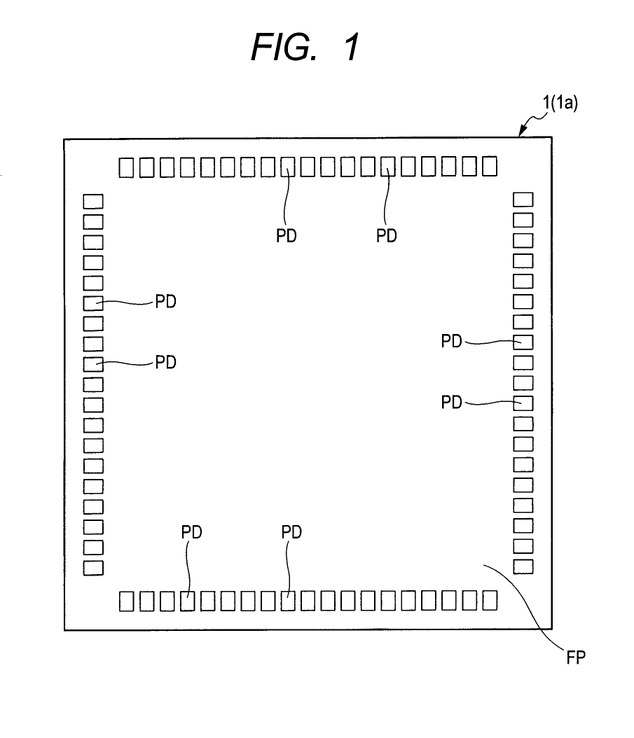

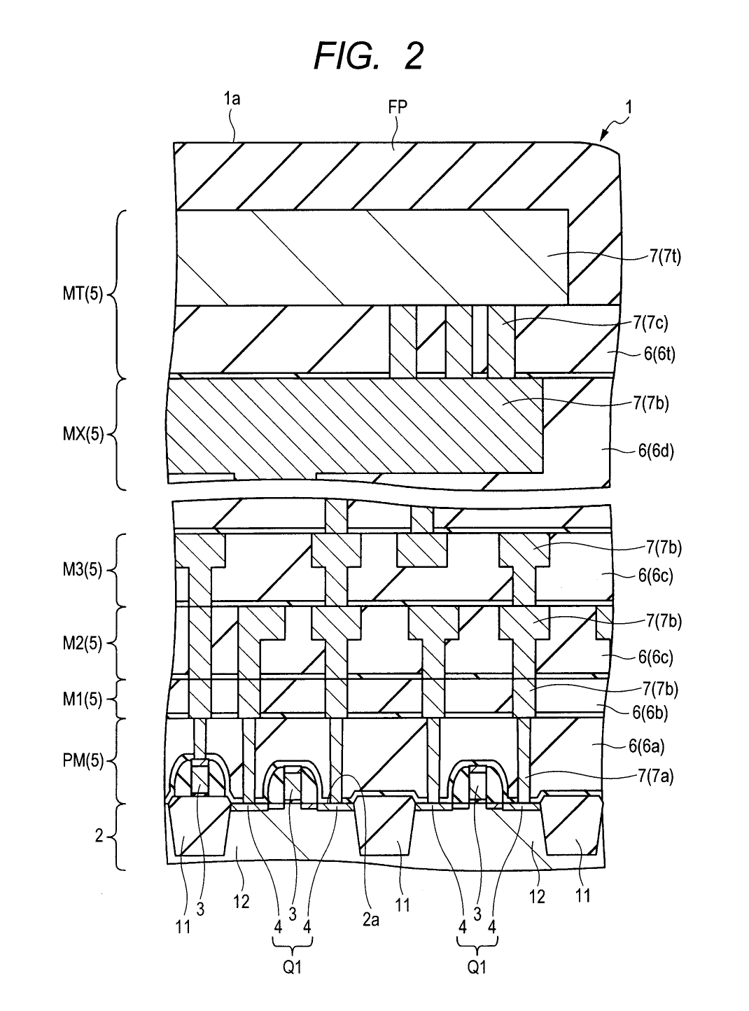

FIG. 1 shows a plan view of one example of an entire structure of a semiconductor device according to one embodiment of the invention, and FIG. 2 shows an enlarged cross-sectional view of one example of a sectional structure of the semiconductor device shown in FIG. 1. As shown in FIG. 1, a semiconductor device (semiconductor chip) 1 of this embodiment has a surface 1a in a rectangular plane shape. The surface 1a is comprised of, for example, a silicon nitride film, a silicon oxide film, or a lamination of a silicon nitride film and a silicon oxide film, and is covered with a passivation film (protective film, insulating film, or protective insulating film) FP which is a protective film (protective insulating film). A plurality of pads (electrodes, electrode pads, or bonding pads) PD are formed of, for example, aluminum, along the sides of the surface 1a on the surface 1a side. Each pad PD is exposed from the passivation film FP at each opening formed in the passivation film FP. Each pad PD serves as an external terminal of the semiconductor device 1.

As shown in FIG. 2, a plurality of semiconductor elements Q1 are formed over a main surface 2a of the semiconductor substrate 2. The semiconductor element Q1 shown in FIG. 2 is, for example, a metal insulator semiconductor field effect transistor (MISFET). Each semiconductor element Q1 includes a gate electrode 3 formed over the main surface 2a, and source and drain regions formed on both sides of the gate electrode 3 over the main surface 2a (hereinafter referred to as source and drain regions 4). A plurality of wiring layers 5 (wiring layers PM, M1, M2, M3, MX, and MT shown in FIG. 2) are laminated over the main surface 2a of the semiconductor substrate 2. Each wiring layer has an insulating film (interlayer insulating film) 6 with a plurality of contact holes (holes or openings) and wiring trenches (trenches or openings). The contact holes and wiring trenches are filled with conductive films (wirings) 7. Via the conductive film 7, a lower wiring layer 5 (or an electrode of the semiconductor element Q1) is electrically coupled to an upper wiring layer 5. A wiring (uppermost layer wiring) 7t and the pads PD (see FIG. 1) are formed in the uppermost wiring layer MT. The pads PD are coupled to the wiring it formed in the wiring layer MT. The pads PD are electrically coupled to the semiconductor element Q1 via the wiring layers 5 (in detail, the conductive film 7 of each wiring layer 5) formed under the pads.

In this embodiment, each wiring layer 5 includes an insulating film 6 containing silicon as a principal component, and the conductive film 7 made of a metal film. The insulating film 6 and the conductive film 7 can be formed by different deposition methods, or can be formed of materials of different components, for each wiring layer 5 formed. For example, in this embodiment, the wiring layer PM positioned in the lowest layer and serving as a contact layer abutted against each semiconductor element Q1 has an insulating film 6a formed of a silicon oxide (SiO₂) film by a chemical vapor deposition (CVD) method. Specifically, the wiring layer is a lamination of an ozone TEOS (tetra-ethyl-ortho-silicate) film which is a silicon oxide film formed by a thermal CVD method using ozone (O₃) and TEOS, and a plasma TEOS film which is a silicon oxide film formed by a plasma CVD method using the TEOS. Each of the plugs (contact plug or conductive film) 7a of the wiring layer PM is comprised of a conductive film containing tungsten (W) as a principal component. Specifically, the plug 7a is comprised of a lamination of a tungsten film and a barrier conductive film formed by sequentially depositing a titanium film and a titanium nitride film. An insulating film 6b forming the wiring layer M1 over the wiring layer PM is comprised of, for example, a silicon oxide film formed by plasma CVD. An insulating film 6c in the upper wiring layers M2 and M3 is comprised of a silicon oxide film (SiOC film) doped with carbon (C). The upper wiring layer MX has an insulating film 6d formed of, for example, fluorosilicate glass (FSG). The uppermost wiring layer MT has an insulating film 6t formed of undoped silicate glass (USG). The conductive film 7 which is a plug or wiring of each of the wiring layers M2, M3, and MX has a conductive film 7b formed of, for example, metal containing copper (Cu) as a principal component. Specifically, the conductive film 7b is comprised of a barrier conductive film formed of a tantalum (Ta) film, a tantalum nitride (TaN) film, or a lamination of these films, and a main conductive film formed of copper or a copper alloy over the barrier conductive film. The conductive film 7c serving as a plug for coupling the uppermost wiring layer MT to the lower wiring layer MX is formed of, for example, tungsten. The wiring 7t formed in the uppermost layer is formed of, for example, aluminum. For example, a silicon nitride film (SiCN film) doped with carbon (C) is formed at an interface between the wiring layers 5 more thinly than the insulating film 6 as the main insulating film. The silicon nitride film serves as a stopper insulating film (etching stopper film) for forming the opening by etching.

### <Outline of Manufacturing Method of Semiconductor Device>

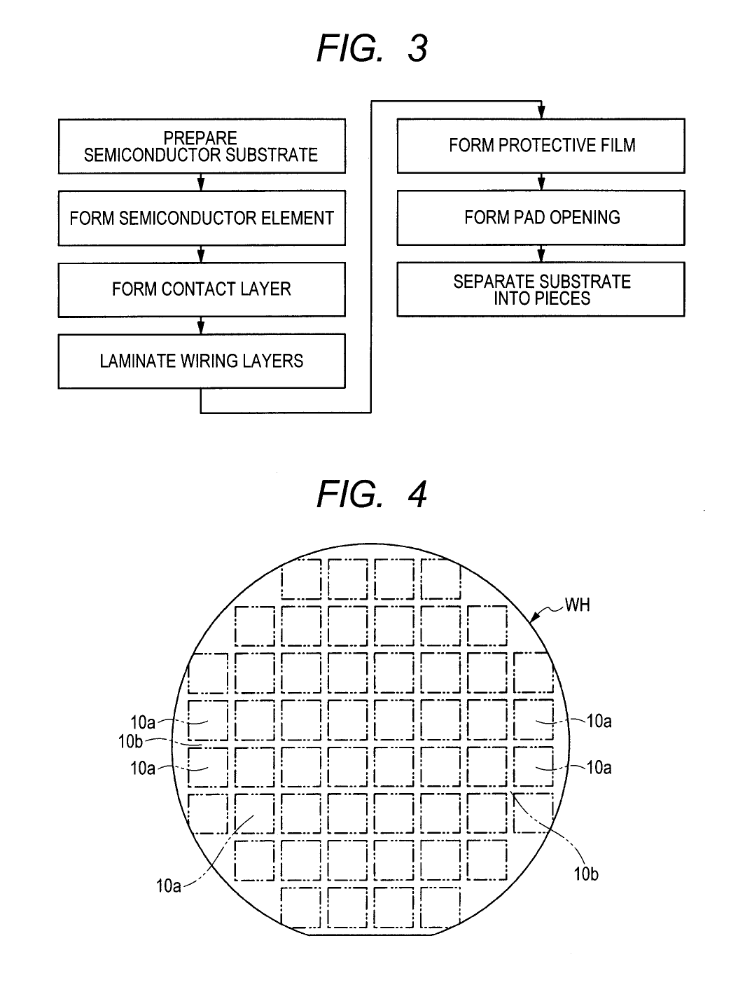

Next, the outline of a manufacturing method of the semiconductor device shown in FIGS. 1 and 2 will be described below. FIG. 3 shows an explanatory diagram of the outline of a manufacturing process flow of the semiconductor device shown in FIGS. 1 and 2. FIG. 4 shows a plan view of the semiconductor substrate prepared in a semiconductor substrate preparation step shown in FIG. 3. One example of the manufacturing method of the semiconductor device shown in FIGS. 1 and 2 will be briefly described using FIG. 3 as follows.

First, in the semiconductor substrate preparation step, wafer (semiconductor substrate) WH shown in FIG. 4 is prepared. As shown in FIG. 4, the wafer WH is formed of a flat plate in a substantially circular plane shape, and is partitioned into a plurality of chip regions (device regions) 10a, each having, for example, a rectangular shape in a planar view. Scribing regions (dicing regions) 10b are arranged between the chip regions 10a.

After the semiconductor substrate preparation step, in a semiconductor element formation step, a plurality of semiconductor elements Q1 (see FIG. 2), such as a transistor or a diode, are formed over the main surface 2a of the wafer WH (see FIG. 2). In this step, for example, as shown in FIG. 2, element isolation regions 11 and well regions 12 are formed at the main surface 2a of the wafer WH (see FIG. 4). The element isolation region 11 is formed of, for example, a silicon oxide film, by a shallow trench isolation (STI) method, a local oxidization of silicon (LOCOS) method, or the like. The well region 12 is a semiconductor region containing p-type or n-type conductive impurities. The well region 12 is formed by ion-implanting the impurities into a region where the semiconductor element Q1 is to be formed. For example, p-type impurities, such as boron (B), are ion-implanted into the region where an n-channel semiconductor element Q1 is to be formed to thereby form the p-type well region (p-type well region) 12. For example, n-type impurities, such as phosphorus (P) or arsenic (As), are ion-implanted into the region where a p-channel semiconductor element Q1 is to be formed to thereby form the n-type well region (n-type well region) 12. Thereafter, the gate electrode 3 and the source and drain regions 4 are formed in the well region 12 of the main surface 2a to form the semiconductor element Q1. The gate electrode 3 is formed by laminating a polysilicon film (for example, a polycrystal silicon film containing impurities) over a gate oxide film comprised of, for example, a thin silicon oxide film of 2 nm to 4 nm in thickness. A sidewall insulating film is formed on each side of the gate electrode 3. The source and drain regions 4 are formed by ion-implanting the impurities into both sides next to the gate electrode 3. For example, n-type impurities, such as phosphorus (P) or arsenic (As), are ion-implanted into the p-type well region 12 where the n-channel semiconductor element Q1 is to be formed, so that the source and drain regions 4 as the n-type semiconductor region are formed. Further, p-type impurities, such as boron (B), are ion-implanted into the region where the p-channel semiconductor element Q1 is to be formed, so that the source and drain regions 4 are formed as the p-type semiconductor region. A metal silicide film is laminated on each of the gate electrode 3 and the source and drain regions 4. The metal silicide film is formed by forming a metal film, for example, a cobalt (Co) film or a nickel (Ni) film, on each of the gate electrode 3 and the source and drain regions 4, and by applying a heat treatment (annealing process) to the metal film, thus causing the reaction between the metal film and the silicon to thereby silicide the metal film.

After the semiconductor element formation step, in a contact layer formation step, the wiring layer PM is formed to serve as the contact layer abutted against each semiconductor element Q1 shown in FIG. 2. Then, a plurality of wiring layers 5 are laminated over the main surface 2a (over the wiring layer PM) in a wiring layer lamination step. The details of the contact layer formation step and the wiring layer lamination step will be described later, but the outline of these steps will be as follows. After forming the insulating film 6 over the base layer (semiconductor substrate 2 or the lower wiring layer 5), the openings are formed in the insulating film 6. Then, the conductive film 7 is embedded in each opening to form a plug or a wiring. The planarization process is applied to the upper surface of the wiring layer 5, for example, by a chemical mechanical polishing (CMP) method to planarize the upper surface. In this way, the wiring layer 5 with the conductive film 7 exposed at the lower and upper surfaces of the insulating film 6 is formed. By repeating this process, the wiring layers 5 can be laminated. The uppermost layer wiring 7t is formed by depositing a metal film of aluminum over the uppermost layer insulating film 6t planarized, for example, through sputtering, and by patterning the metal film through etching. At this time, the pads PD (see FIG. 1) are also formed to be coupled to the wiring 7t.

In a protective film formation step after the wiring layer lamination step, the passivation film (protective film, insulating film, or protective insulating film) FP is formed (deposited) over the uppermost layer wiring 7t. In this step, for example, a silicon nitride film, a silicon oxide film, or a lamination of a silicon nitride film and a silicon oxide film is deposited by the CVD method to cover the wiring 7t and the pads PD (see FIG. 1) coupled thereto. Then, in a pad opening formation step, a plurality of openings are formed in the passivation film FP, from which the pads PD (see FIG. 1) are exposed at the openings. Then, after performing an electrical checking step or the like, in a separation step, the wafer WH (see FIG. 4) is divided and separated into pieces of the chip regions 10a (see FIG. 4). In this step, for example, a cutter called “dicing blade” moves along the scribing regions 10b of the wafer WH shown in FIG. 4 to divide the wafer WH. Thus, a plurality of semiconductor devices 1 (see FIG. 1) can be obtained from one piece of the wafer WH.

### <Details of Wiring Layer Lamination Step>

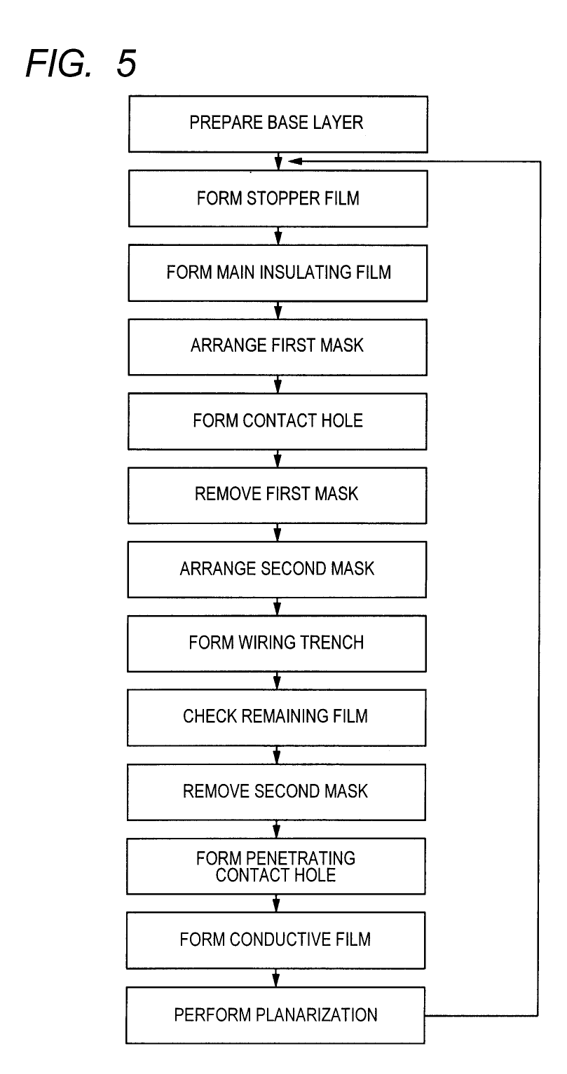

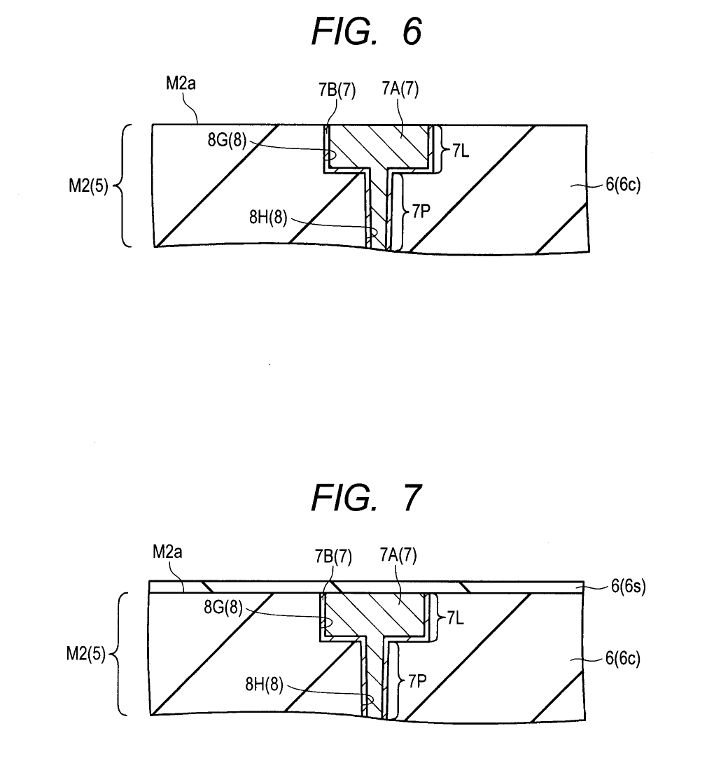

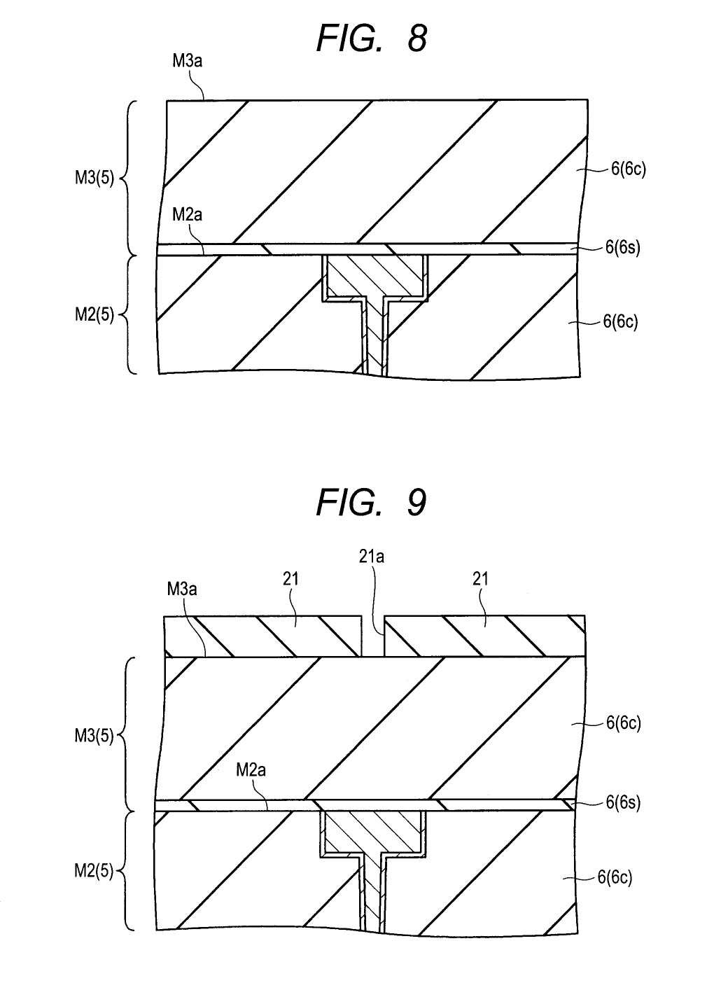

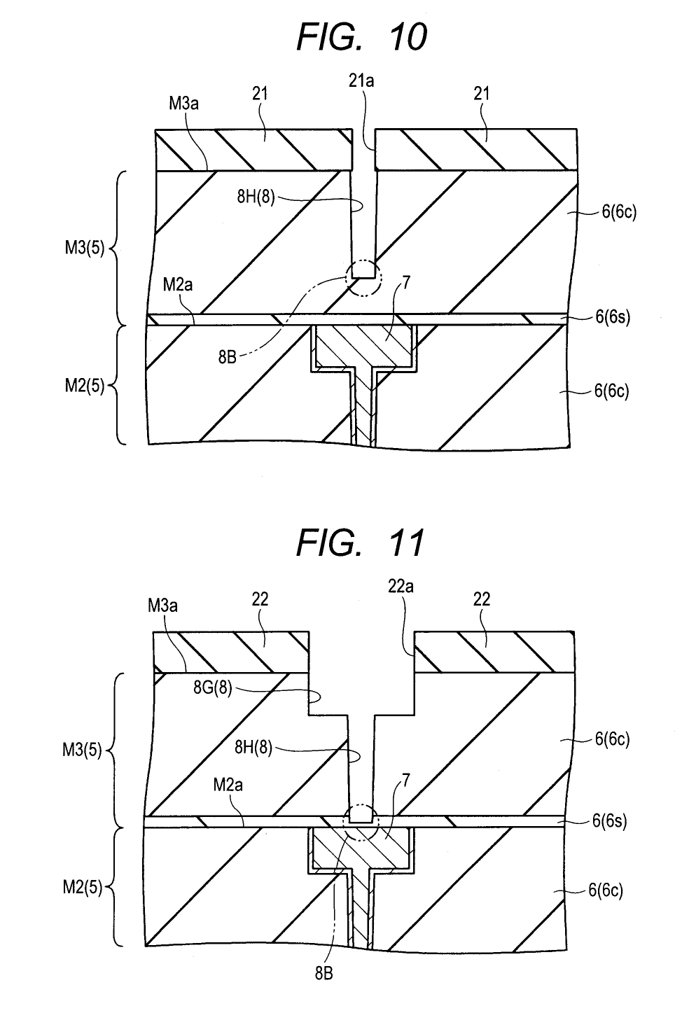

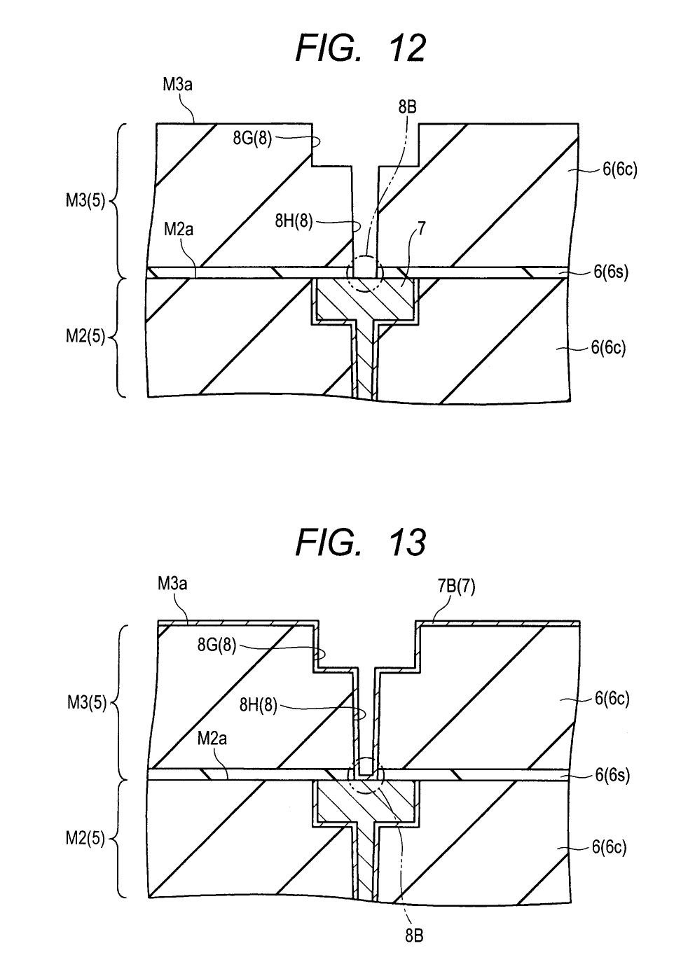

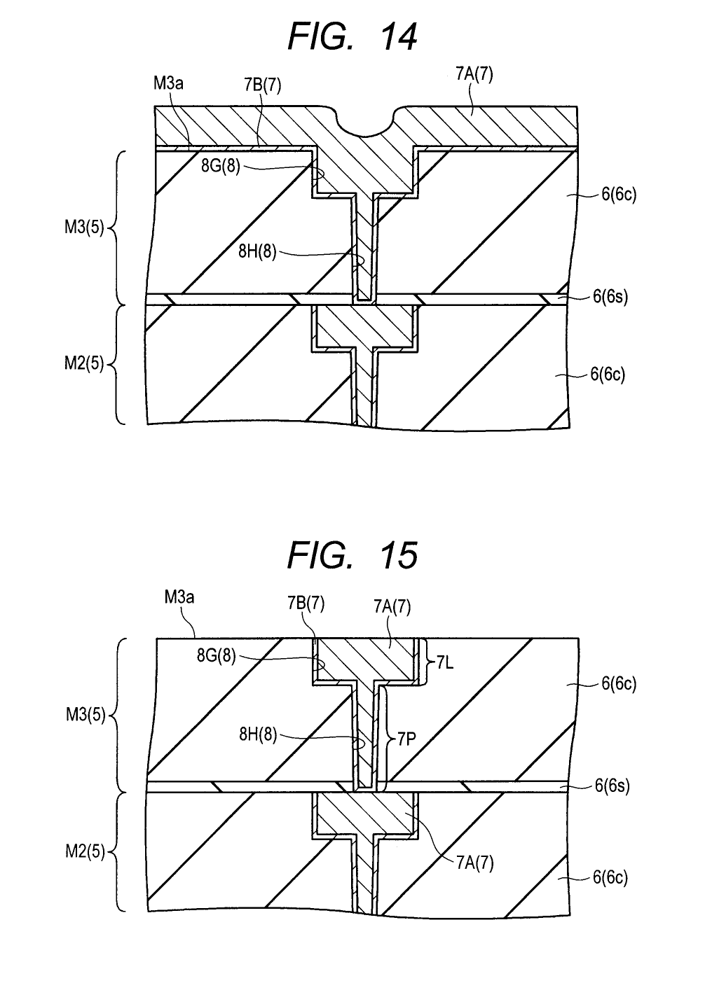

In the above contact layer formation step and the wiring layer lamination step, the openings, such as the contact hole or wiring trench, are formed in the insulating film 6, and the conductive film 7 is embedded in each opening to thereby form a plug or wiring. Now, the step of embedding the conductor in each opening after formation of the openings will be described in detail by taking the step of formation of the wiring layer M3 shown in FIG. 2 as an example. FIG. 5 shows an explanatory diagram of a process flow of the wiring layer lamination step shown in FIG. 3. FIG. 6 shows an enlarged cross-sectional view of the state of formation of a base layer of the fourth wiring layer shown in FIG. 2. FIG. 7 shows an enlarged cross-sectional view of the state of an etching stopper film deposited on the upper surface of the wiring layer shown in FIG. 6. FIG. 8 shows an enlarged cross-sectional view of the state of a main insulating film deposited on the etching stopper film shown in FIG. 7. FIG. 9 shows an enlarged cross-sectional view of the state of a mask disposed on the main insulating film shown in FIG. 8 so as to form a contact hole. FIG. 10 shows an enlarged cross-sectional view of the state of the contact hole formed in the insulating film shown in FIG. 9. FIG. 11 shows an enlarged cross-sectional view of the state of a wiring trench formed by disposing another mask for forming the wiring trench after removing the mask shown in FIG. 10. FIG. 12 shows an enlarged cross-sectional view of the state of removal of a remaining film under the contact hole after removing the mask shown in FIG. 11. FIG. 13 shows an enlarged cross-sectional view of the state of a barrier conductive film deposited in an opening after removing the remaining film at the bottom of the opening shown in FIG. 12. FIG. 14 shows an enlarged cross-sectional view of the state of a main conductive film embedded in the opening shown in FIG. 13. FIG. 15 shows an enlarged cross-sectional view of the state of removal of the conductive film on the upper surface of the insulating film by performing a planarization process on the upper surface of the insulating film shown in FIG. 14.

In a base layer preparation step of the wiring layer lamination step shown in FIG. 3, first, a layer serving as a base layer for the wiring layer is formed. Since FIG. 6 is a diagram for explaining the step of forming the wiring layer M3 shown in FIG. 2, the wiring layer M2 corresponds to the base layer. The insulating film 6 and the openings 8 penetrating the insulating film 6 are formed in the wiring layer M2, and the conductive film (base film) 7 is embedded in each opening 8. The planarization process is applied to the upper surface M2a of the wiring layer M2, so that the conductive film 7 is exposed at the opening 8 of the upper surface M2a from the insulating film 6. Then, in a stopper film formation step, as shown in FIG. 7, a stopper insulating film (film to be measured) 6s is deposited (formed). The stopper insulating film 6s is formed of, for example, a silicon carbonitride film (SiCN film) doped with carbon (C), for example, in a thickness of about 30 nm to 50 nm by the CVD method. In this step, the part of the conductive film 7 (main conductive film (base film) 7A, and barrier conductive film 7B) exposed from an insulating film 6c is covered with the stopper insulating film 6s at the upper surface M2a of the wiring layer M2.

Then, in a main insulating film formation step, the insulating film 6c which is a main interlayer insulating film, is deposited (formed, or laminated) over the stopper insulating film 6s as shown in FIG. 8. The insulating film 6c is formed of, for example, a silicon oxycarbide film (SiOC film) doped with carbon (C), for example, in a thickness of 300 nm to 500 nm, which is more than that of the stopper insulating film 6s, by the CVD method. Then, in a first mask arrangement step, a resist film 21 is arranged over an upper surface M3a of the insulating film 6c as shown in FIG. 9. The resist film 21 serves as a mask for forming a contact hole 8H (see FIG. 10) in the insulating film 6c as the main insulating film. Through holes 21a penetrating the resist film 21 in the thickness direction are formed in positions where the contact holes 8H are to be formed, using the resist film 21 as a mask pattern.

Then, in a contact hole formation step, as shown in FIG. 10, parts of the insulating film 6c are removed toward the wiring layer M2 as the base layer from the upper surface M3a of the insulating film 6c using the resist film 21 as the mask to thereby form the contact holes (openings or holes) 8H. The method for removing the part of the insulating film 6c involves, for example, performing etching on the insulating film 6c using the resist film 21 as an etching mask to form the contact holes 8H. The etching for use can include dry etching, wet etching, and a combination thereof. Since the wiring trenches coupled to the contact holes 8H are also formed in the wiring layer M3, at the end stage of this step, each contact hole 8H does not completely penetrate the insulating film 6c as shown in FIG. 10, and the bottom 8B of the contact hole 8H is disposed at the midway point of the insulating film 6c. Then, in a first mask removal step (ashing step), the resist film 21 shown in FIG. 10 is removed. Since the conductive film 7 of the wiring layer M2 as the base layer is covered with the stopper insulating film 6s and the part of the insulating film 6c above the film 6s, the conductive film 7 can be prevented from being contaminated during the ashing process. After the ashing process, the cleaning process is often performed so as to remove the residue of the resist film 21. In this case, the conductive film 7 of the wiring layer M2 is covered with the stopper insulating film 6s and the insulating film 6c above the film 6s, so that the conductive film 7 can be prevented from being contaminated during the cleaning process.

Then, in a second mask arrangement step, as shown in FIG. 11, a resist film 22 is arranged over the upper surface M3a of the insulating film 6c. The resist film 22 is a mask for forming wiring trenches (openings) 8G in the insulating film 6c as the main insulating film. Openings 22a penetrating the resist film 22 in the thickness direction are formed in positions where the wiring trenches 8G are to be formed, using the resist film 22 as a mask pattern. The resist film 22 is a mask for forming the wiring trenches 8G. The opening 22a is formed more widely than the through hole 21a of the resist film 21 shown in FIG. 10. Then, in a wiring trench formation step, the parts of the insulating film 6c and the stopper insulating film 6s are removed from the upper surface M3a of the insulating film 6c toward the wiring layer M2 as the base layer using the resist film 22 as a mask to thereby form the wiring trenches (openings or trenches) 8G. Like the contact hole formation step, the method of removing the parts of the insulating film 6c and the stopper insulating film 6s involves, for example, performing etching using the resist film 22 as an etching mask to form the wiring trenches 8G. At this time, each contact hole 8H is also exposed from the resist film 22 at the opening 22a of the resist film 22. The part of the insulating film 6 located under the bottom 8B of the contact hole 8H as shown in FIG. 10 is further removed. Thus, the contact hole 8H is further extended downward to penetrate the insulating film 6c in the thickness direction. In this embodiment, the insulating film 7c is formed of a silicon oxide based film, and the stopper insulating film 6s is formed of a silicon, nitride based film. Thus, in this step, the use of etching material for the silicon oxide film (etching gas in the dry etching, or etchant in the wet etching) can prevent the etching from penetrating the stopper insulating film 6s. Even when using the etching material for the silicon oxide film, the part of the stopper insulating film 6s is removed by the etching.

In this step, as shown in FIG. 11, the part of the stopper insulating film 6s remains as a remaining film under the bottom 8B of the contact hole 8H without causing the hole 8H to penetrate the stopper insulating film 6s. Thus, in a second mask removal step shown in FIG. 5, the conductive film 7 in the wiring layer M2 as the base layer can be prevented from being contaminated during the ashing process or cleaning process. In order to surely remove the remaining film of the stopper insulating film 6s in a contact hole penetration step shown in FIG. 5, the remaining film is preferably thin. For example, in this embodiment, the remaining film of the stopper insulating film 6s is controlled to be within a range of several nm to 20 nm. The thickness of the remaining film can be controlled, for example, by the processing time of etching. However, when the remaining film of the stopper insulating film 6s is controlled to be within the range of about several nm to 20 nm like this embodiment, the control performed only by the etching processing time will disadvantageously cause the etching to penetrate the stopper insulating film 6s. For this reason, in this embodiment, as shown in FIG. 5, the presence or absence of the remaining film, or the thickness of the remaining film is checked by performing the remaining film checking step after the wiring trench formation step. The result of the remaining film checking step is feedbacked to the manufacturing process, which can control the thickness of the remaining film of the stopper insulating film 6s with high accuracy. For example, when there occurs the failure of penetration into the stopper insulating film 6s or the failure of the thickness of the remaining film exceeding the allowable level, the occurrence of the failure can be detected in the remaining film checking step. Thus, if the manufacturing is stopped at the time of detection of the failure, the loss of products due to mass production of defective products can be prevented. The causes for the failures are specified by checking conditions of the manufacturing process, so that the conditions can be corrected to new conditions reflecting the causes. In order to detect only the failure of penetration into the stopper insulating film 6s, the detection of only the presence or absence of the remaining film is required in the remaining film checking step. In contrast, in order to detect the failures, including the failure of the thickness of the remaining film exceeding the allowable level, it is necessary to detect the thickness of the remaining film. Now, a specific checking method in the remaining film checking step will be described below.

Then, in a second mask removal step (ashing step), the resist film 22 shown in FIG. 11 is removed. Since the conductive film 7 of the wiring layer M2 as the base layer is covered with the remaining film of the stopper insulating film 6s disposed under the bottom 8B of the contact hole 8H at this time, the conductive film 7 can be prevented from being contaminated during the ashing process. After the ashing process, the cleaning process is often performed so as to remove the residue of the resist film 22. In this case, the conductive film 7 of the wiring layer M2 is covered with the remaining film of the stopper insulating film 6s disposed under the bottom 8B of the contact hole 8H, so that the conductive film 7 can be prevented from being contaminated during the cleaning process.

Then, in a contact hole penetration step, as shown in FIG. 12, the remaining film of the stopper insulating film 6s under the contact hole 8H is removed. In this step, the removal of the remaining film of the stopper insulating film 6s causes the contact hole 8H to penetrate the stopper insulating film 6s in the thickness direction. Thus, the conductive film 7 in the wiring layer M2 as the base layer is exposed at the bottom 8B of the contact hole 8H from the stopper insulating film 6s. The method for removing the remaining film of the stopper insulating film 6s can be the etching. In this step, the use of the etching material for a silicon nitride film can selectively (preferentially) remove the stopper insulating film 6s without forming an etching mask. In the above wiring trench formation step, the thickness of the remaining film of the stopper insulating film 6s is set to, for example, about several nm to 20 nm, which can shorten the processing time of etching.

Then, in a conductive film formation step, a conductive film is formed inside the contact hole 8H and the wiring trench 8G shown in FIG. 12. As shown in FIG. 13, first, a barrier conductive film 7B for preventing or suppressing the diffusion of components of the main conductive film into the insulating film 6c is deposited (formed) in the contact hole 8H and the wiring trench 8G. The barrier conductive film 7B is formed of, for example, a tantalum (Ta) film, a tantalum nitride (TaN) film, or a lamination of the tantalum film and the tantalum nitride film, for example, in a thickness of about 10 nm. The barrier conductive film 7B is formed, for example, by sputtering or CVD method. In this step, the barrier conductive film 7B is deposited over the inner wall surfaces of the contact hole 8H and the wiring trench 8G, and the upper surface M3a of the insulating film 6c without placing the mask over the upper surface M3a of the insulating film 6c. Then, as shown in FIG. 14, a main conductive film 7A is deposited (formed) over the barrier conductive film 7B to fill the contact holes 8H and the wiring trenches 8G. The main conductive film 7A is formed of, for example, copper (Cu) by sputtering, electric plating, or the like. The main conductive film 7A can be formed of a conductive film containing copper as a principal component, for example, copper or a copper alloy (containing Cu as a principal component, and, for example, Mg, Ag, Pd, Ti, Ta, Al, Nb, Zr, Zn, or the like). A seed film is formed of copper (or copper alloy) thinner than the main conductive film, over the barrier conductive film 7B by the sputtering or the like. On the seed film, a main conductive film 7A can be formed of copper (or copper alloy) thicker than the seed film by plating or the like.

Then, in a planarization step, the planarization process is applied to the upper surface M3a of the insulating film 6c. Since the barrier conductive film 7B and the main conductive film 7A are formed along the shape of the openings 8 including the contact holes 8H and the wiring trenches 8G, the surface of the film 7A becomes a concave-convex surface as shown in FIG. 14. Thus, the excessive parts of the barrier conductive film 7B and the main conductive film 7A are removed, for example, by the planarization using the CMP method (metal CMP method). In the planarization step, the barrier conductive film 7B and the main conductive film 7A formed over the upper surface M3a of the insulating film 6c are removed.

After completion of the planarization step, the wiring layer M3 is formed as shown in FIG. 15. The insulating film 6 and the openings 8 penetrating the insulating film 6 are formed in the wiring layer M3, and the conductive film 7 is embedded in each opening 8. Specifically, the conductive film 7 is embedded in the contact hole 8H, and is comprised of a plug 7P in contact (connection) with the main conductive film 7A of the lower wiring layer M2, and a wiring (embedded wiring) 7L disposed above the plug 7P and integrally formed with the plug 7P. The planarization process is applied to the upper surface M3a of the wiring layer M3, so that the conductive film 7 is exposed from the insulating film 6 at each opening 8 of the upper surface M3a. Thus, the wiring layer M3 serves as a base layer of the wiring layer 5 to be laminated thereon. That is, in the wiring layer lamination step shown in FIG. 3, the processes from the stopper film formation step to the planarization step shown in FIG. 5 are repeatedly performed to laminate the wiring layers 5.

This embodiment has described the so-called dual damascene process in which the wiring layers 5 are formed by forming the contact holes 8H and the wiring trenches 8G coupled thereto in the insulating films 6, and by filling each opening 8 with the conductive film 7. The formation method of the wiring layer 5, however, is not limited to the above method. For example, the formation method can be applied to another method which involves embedding the conductive film 7 in each contact hole 8H without forming the wiring trenches 8G, performing the planarization process, and then forming the wiring 7L on each plug 7P. For example, the formation method can also be applied to a further method which involves embedding the conductive film 7 in each contact hole 8H before formation of the wiring trenches 8G, applying the planarization process to the film, laminating the insulating film 6 thereon, and then forming the wiring trench 8G and the wiring 7L filling the wiring trenches 8G in the laminated insulating films 6.

### <Details of Remaining Film Checking Step>

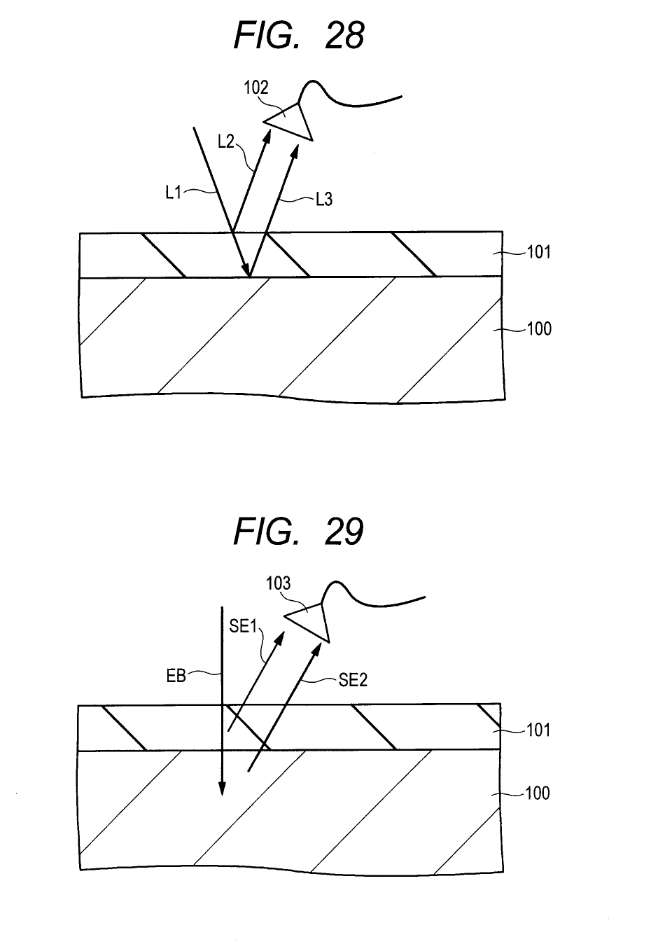

Next, the details of the remaining film checking step shown in FIG. 5 will be described below. In this section, first, after explaining comparative examples studied by the inventors of the present application, the contents of the remaining film checking step of this embodiment will be described below. FIG. 28 is an explanatory diagram exemplarily showing a remaining film checking step as a first comparative example with respect to this embodiment. FIG. 29 is an explanatory diagram exemplarily showing a remaining film checking step as a second comparative example with respect to this embodiment.

In the remaining film checking step shown in FIG. 5, the presence or absence or the thickness of a thin film of about several nm to 20 nm in thickness under the bottom 8B of the contact hole 8H is measured as shown in FIG. 11. In order to effectively perform such a remaining film checking step, a non-contact checking process may be preferably performed. The inventors of the present application have studied methods for measuring the thickness of a film using optical interference as a non-contact check method as shown in FIG. 28. The film thickness measuring method using the optical interference first involves applying an irradiation light L1 to an object of interest to be checked which includes a base film 100 and a film to be measured 101 laminated on the base film 100, as shown in FIG. 28. A part of the irradiation light L1 is reflected by the surface of the film 101 to be measured to generate a reflection light L2. Another part of the irradiation light L1 penetrates the film 101 to be measured and is reflected by the surface of the base film 100 (that is, the back surface of the film to be measured) to generate another reflection light L3. A difference in phase between the reflection light L2 and the reflection light L3 is made depending on the thickness of the film to be measured. In the film thickness measuring method shown in FIG. 28, a phase detector 102 is disposed over the film 101 to be measured, and the difference in phase between the reflection lights L2 and L3 is detected by the phase detector 102, whereby the thickness of the film 101 to be measured is calculated from the difference in phase. When applying the film thickness measuring method using such an optical interference, the region to which the irradiation light L1 is applied needs to be a flat surface having about an area of about several tens to several hundreds of μm². On the other hand, the bottom 8B of the contact hole 8H has a fine pattern having a planar size, for example, smaller than 1 μm². Thus, the film thickness measuring method using the optical interference shown in FIG. 28 cannot be applied as the remaining film checking step shown in FIG. 5.

Next, the inventors of the present application have studied other non-contact detection methods which involve measuring the presence or absence or the thickness of the film 101 to be measured by applying an electron beam EB to the object of interest to be detected to detect secondary electrons emitted from the film to be measured as shown in FIG. 29. In the method shown in FIG. 29, the electron beam EB is applied from the film 101 side to be measured to the object of interest to be checked. Then, secondary electrons SE1 excited by the electron beam EB from the film 101 to be measured are emitted. When the acceleration voltage of the electron beam EB is heightened to increase the intensity of the electron beam EB (energy strength), secondary electrons SE2 excited by the electron beam EB from the base film 100 under the film 101 to be measured are also emitted. The secondary electrons SE1 and SE2 emitted from the upper surface side of the film to be measured are detected by a secondary electron detector 103. When the film 101 to be measured is an insulating film and the base film 100 is a conductive film made of metal or the like, the amount of the secondary electrons SE2 is more than that of the secondary electrons SE1. Thus, when the acceleration voltage of the electron beam EB is gradually increased to increase the intensity of the electron beam EB, a point of change in amount of generated secondary electrons is caused. By using the film 101 to be measured for evaluation whose thickness is known, a correlation between the point of change in amount of generated secondary electrons and the intensity of the electron beam EB is examined in advance. Then, by comparison with the result of the examination, the thickness of the film 101 to be measured can be measured. The inventors of the present application, however, further have studied the film thickness measuring method shown in FIG. 29, and, as a result, have found the following problems.

When the measuring method is applied to measurement of the remaining film of the stopper insulating film 6s under the bottom 8B of the contact hole 8H as shown in FIG. 11, the accuracy of measurement of the remaining film is reduced, or the measurement thereof is made impossible. For example, when an aspect ratio of the opening 8 is large, the secondary electrons SE1 and SE2 (see FIG. 29) emitted from the film 101 to be measured (see FIG. 29) or the base film 100 (see FIG. 29) are easily absorbed in the wiring trench 8G or sidewall (insulating film 6c) of the contact hole 8H. As a result, the amount of detected secondary electrons SE1 and SE2 is decreased, which reduces the accuracy of measurement or makes the measurement impossible. Further, the system for evaluating the intensity of signals of the secondary electrons SE1 and SE2 is apt to be affected by noise due to the insulating film 6. Thus, the accuracy of measurement tends to be easily decreased by the noise. The intensity of signals of the secondary electrons SE1 and SE2 are changed according to the pattern of the opening 8, which makes, it difficult to make comparison with the result of examination using the film to be measured 101 for evaluation whose thickness is known. When the film 101 to be measured and the base film 100 are formed of materials which have the similar characteristics of secondary electron emission (for example, metal films), a difference in amount of emitted secondary electrons between the film 101 to be measured and the base film 100 is not obvious, which reduces the accuracy of measurement, or makes the measurement impossible.

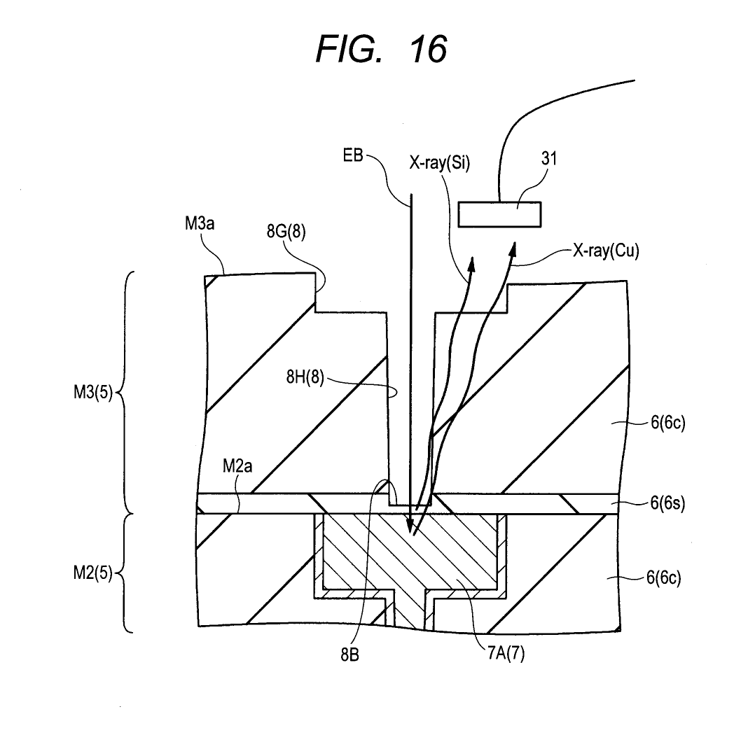

Taking into consideration the above results of studies, the remaining film checking step of this embodiment will be described below. FIG. 16 is an explanatory diagram exemplarily showing the remaining film checking step shown in FIG. 5. In the remaining film checking step of this embodiment, first, the electron beam (excitation beam) EB is directed to each opening 8 (in detail, the bottom 8B of the contact hole 8H). When the electron beam EB is applied to each opening 8, not only the secondary electrons described in the above second comparative example, but also characteristic X-rays (for example, characteristic X-rays exemplarily shown as X-rays (Si) in FIG. 16) are emitted from the remaining film of the stopper film 6s as the film to be measured. When the intensity of the electron beam EB is increased, the conductive film 7 as the base layer is excited to emit characteristic X-rays (for example, characteristic X-rays exemplarily shown as X-rays (Cu) in FIG. 16) from the conductive film 7. These characteristic X-rays are X-rays generated when electrons make transition to holes generated by emission of other electrons from excited atoms. Thus, the characteristic X-ray has a single energy (line spectrum), whose value is an intrinsic value for each element emitting the electron (which is called “characteristic X-ray”). For example, the stopper insulating film 6s emits the characteristic X-rays of silicon (Si), oxygen (O), carbon (C), and nitrogen (N). For example, the main conductive film 7A comprised of copper (Cu) emits the characteristic X-rays of copper (Cu) element. In some cases, the main conductive film 7A also emits the characteristic X-rays of silicon (Si) from silicon components dispersed into the main conductive film 7A. In this embodiment, the presence or absence of the remaining film, or the thickness of the remaining film is determined (evaluated) by detecting the characteristic X-rays. Specifically, a plurality of element components contained in the characteristic X-rays emitted from the film to be measured and the base film are detected by the X-ray detecting portion 31 disposed on the upper surface M3a side of the wiring layer M3. For example, a silicon (Si) element component is detected as a main element component from the stopper insulating film 6s, and a copper (Cu) element component is detected as a main element component from the main conductive film 7A. Then, the presence or absence or the thickness of the film to be measured is determined (evaluated) by the ratio of a plurality of kinds of element components. For example, by comparison between the copper (Cu) element component and the silicon (Si) element component, the ratio of these components (copper (Cu) element component to silicon (Si) element component, that is, Cu element component/Si element component) is determined to thereby determine (evaluate) the presence or absence or the thickness of the remaining film of the stopper insulating film 6s. Now, the evaluation method will be described below.

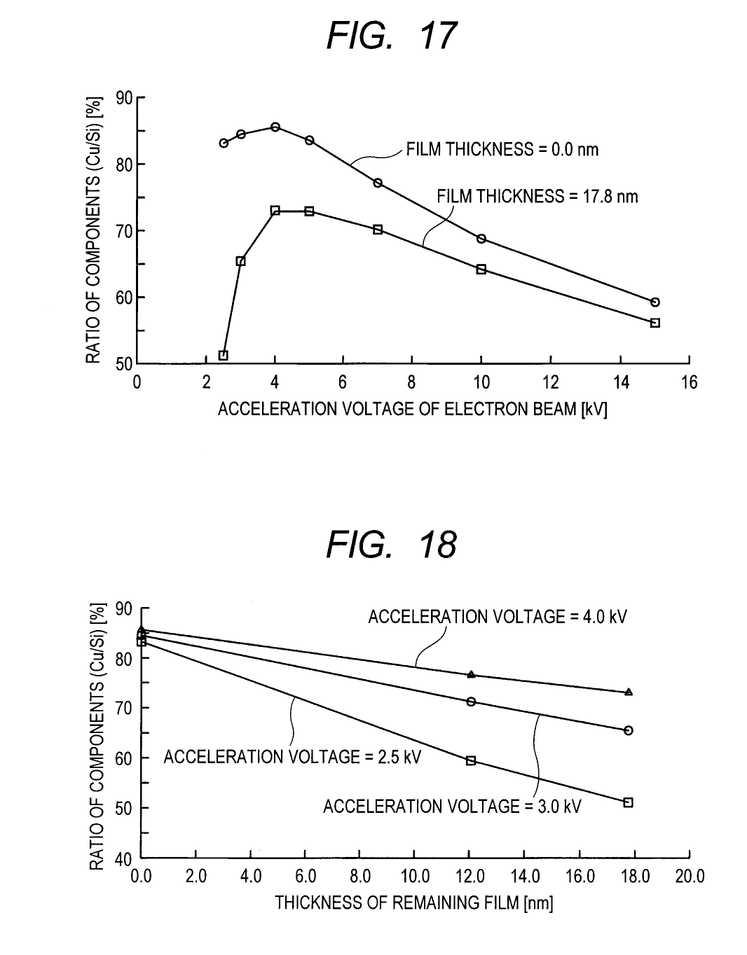

FIG. 17 shows an explanatory diagram of the relationship between the presence or absence of the remaining film and the ratio of components (Cu/Si) when changing the intensity (acceleration voltage) of the electron beam applied to the opening shown in FIG. 16. FIG. 18 shows an explanatory diagram of the relationship between the thickness of the remaining film and the ratio of components (Cu/Si) at each intensity (acceleration voltage) of the electron beam applied to the opening shown in FIG. 16. A plurality of kinds of samples having the stopper insulating films 6s with different known thicknesses shown in FIG. 16 were made. The correlation between the ratio of components of the characteristic X-rays and the intensity of excitation beam was measured by applying the electron beam EB to the plurality of kinds of the samples (see FIG. 16). FIGS. 17 and 18 show the result of the measurement. The spectral analysis system is classified into energy dispersive spectral analysis, and wavelength dispersive spectral analysis. The energy dispersive spectral analysis method performs analysis using an energy dispersive spectroscope, which is called “energy dispersive X-ray spectroscopy (EDS)”. The wavelength dispersive spectral analysis performs analysis using a wavelength dispersive spectroscope, which is called “wavelengh dispersive X-ray spectrometry (WDS)”. The wavelength dispersive spectral analysis has an advantage in that the resolution is easily increased as compared to the energy dispersive spectral analysis. However, from the viewpoint of simplifying the structure of the detector, the energy dispersive spectral analysis is more preferable.

Since the amount of emission of the characteristic X-rays changes according to the intensity of the electron beam EB (see FIG. 16) which is an excitation beam, the intensity (acceleration voltage of electrons) of the appropriate electron beam EB (see FIG. 16) have been studied. The result of the studies is shown in FIG. 17. In order to determine the presence or absence of the remaining film by the ratio of components, this embodiment preferably employs such an intensity of excitation beam that greatly changes the result of measurement of the ratio of components depending on the presence or absence of the remaining film. As shown in FIG. 17, when the acceleration voltage of the electron beam EB (see FIG. 16) is in a range of 2.5 V to 4.0 V, a difference in ratio of components (Cu/Si) between the case of absence of the remaining film (thickness=0.0 nm) and the case of presence of the remaining film (thickness=17.8 nm) is 10% or more. Then, as the acceleration voltage of the electron beam EB (see FIG. 16) is further increased, the difference in ratio of components (Cu/Si) between the presence and absence of the remaining film becomes smaller. In contrast, when the acceleration voltage of the electron beam EB (see FIG. 16) is smaller than 2.5 V, in the presence of the remaining film (thickness=17.8 nm), the rate of a copper (Cu) component which is contained in the characteristic X-rays emitted from the base layer is decreased. This is because, as the intensity of the electron beam EB (see FIG. 16) becomes smaller, the conductive film 7 as the base layer is less likely to be excited. As can be seen from the result shown in FIG. 17, the acceleration voltage of the electron beam EB (see FIG. 16) is more preferably not less than 2.5 V nor more than 4.0 V.

The result of studies about the relationship between the thickness of the remaining film and the ratio of components (Cu/Si) is shown in FIG. 18. FIG. 18 shows the cases of the acceleration voltage of the electron beam EB (see FIG. 16) of 2.5 kV, 3.0 kV, and 4.0 kV. As can be seen from FIG. 18, when the thickness of the remaining film is in a range of 0.0 nm to about 18.0 nm, the thickness of the remaining film is inversely proportional to the ratio of components (Cu/Si). That is, the ratio of components (Cu/Si) is decreased with increasing thickness of the remaining film. Thus, the electron beam EB (see FIG. 16) accelerated at an arbitrary acceleration voltage, for example, in a range of 2.5 kV to 4.0 kV is applied to the opening 8 shown in FIG. 16. The ratio of components of the characteristic X-rays detected is compared with the correlation data obtained by applying an excitation beam to the remaining films with the known thicknesses shown in FIG. 18, whereby the thickness of the actual remaining film can be calculated (determined). That is, the presence or absence or the thickness of the remaining film can be determined (evaluated) by the ratio of a plurality of kinds of element components contained in the detected characteristic X-rays.

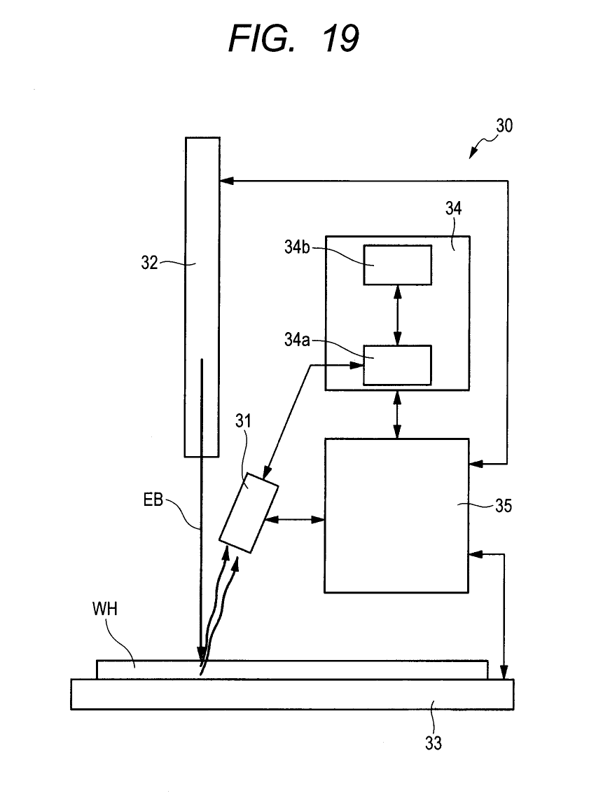

Now, the structure of the remaining film checking device used in the remaining film checking step of this embodiment will be described below. FIG. 19 shows an explanatory diagram of the outline of the structure of the remaining film checking device. A checking device (remaining film checking device) 30 shown in FIG. 19 includes an excitation beam irradiating portion 32 for irradiating the opening with the electron beam EB as the excitation beam, and a substrate fixing portion 33 for fixing the wafer WH which is an object of interest to be checked. The checking device 30 includes a detecting portion 31 for detecting the characteristic X-rays emitted from the wafer WH, and a determination portion 34 for determining the presence or absence or the thickness of the remaining film from detected signal data. The checking device 30 also includes a controller 35 for controlling the operation (mechanical operation or electrical operation) of each of the excitation beam irradiating portion 32, the substrate fixing portion 33, the detecting portion 31, and the determination portion 34.

The excitation beam irradiating portion 32 includes, for example, an electron gun for generating the electron beam EB as the excitation beam, and a lens for allowing the electron beam EB to converge to and to be applied to the bottom 8B (see FIG. 16) of the opening 8 (see FIG. 16) of the wafer WH as the object of interest to be checked. The irradiating portion 32 is disposed over the main surface (above the opening as the object of interest to be checked) of the wafer WH. The excitation beam irradiating portion 32 is electrically coupled to the controller 35, whereby the electron beam EB injected from the electron gun is accelerated at a predetermined acceleration voltage (for example, at an arbitrary acceleration voltage of 2.5 V to 4.0 V) by a control signal from the controller 35, and then applied to the opening 8 (see FIG. 16) on the main surface side of the wafer WH. The detecting portion 31 includes a detector electrically coupled to the determination portion 34 and the controller 35, and is disposed over the main surface of the wafer WH (above the opening as the object of interest to be checked). Detection signals of a plurality of kinds of the characteristic X-rays detected by the detecting portion 31 are transferred to a determination circuit 34a included in the determination portion 34. The detection signals of the characteristic X-rays are dispersed for each element component of the characteristic X-rays, and transferred to the determination circuit 34a. For example, the detecting portion 31 for performing the energy dispersive spectral analysis receives the transmitted detection signal dispersed for each energy of the characteristic X-rays. The detecting portion 31 for performing the wavelength dispersive spectral analysis receives the transmitted detection signal dispersed for each wavelength of the characteristic X-rays.

The determination circuit 34a of the determination portion 34 performs the processing (statistical processing) of a detected signal of the characteristic X-beams for each element component, and then calculates the ratio (data on the ratio of components) of a detection signal of the first element component contained in the film to be measured to another detection signal of the second element component contained in the base layer. The determination portion 34 includes a date holder 34b for holding data for determination. The data for determination is, for example, correlation data obtained by applying the excitation beam to the remaining film having the known thickness, or threshold data set based on the correlation data, as described with reference to FIG. 18. The data for determination is transferred from the data holder 34b to the determination circuit 34a. By comparing the measurement data about the ratio of components with the data for determination, the presence or absence or the thickness of the remaining film is determined (evaluated) at the determination circuit 34a.

In this way, according to this embodiment, the presence or absence or the thickness of the remaining film is determined by detecting the characteristic X-rays radiated from the film to be measured and the base film. The characteristic X-rays are less likely to be absorbed into the circumferential side wall of the opening 8 rather than secondary electrons. Thus, even when the remaining film at the bottom of the opening 8 having a high aspect ratio, such as a through hole, is checked, the characteristic X-rays can be detected. In this embodiment, the presence or absence or the thickness of the remaining film is determined not by an absolute value of the detected characteristic X-rays, but by the ratio of element components contained in the characteristic X-rays. Thus, this embodiment can suppress the reduction in accuracy of measurement even when the intensity of a signal changes due to the influence of a peripheral pattern of the opening 8 of interest to be measured, or due to noise from the insulating film 6c. In this embodiment, the film to be measured is an insulating film (stopper insulating film 6s), and the base film is a conductive film (main conductive film 7A). However, the invention is not limited thereto, and can be applied to any other structure of a base film and a film to be measured which can be detected by a system for detecting characteristic X-rays. For example, the invention can be applied to the case where both a film to be measured and a base film are comprised of insulating films or conductive films having different components. Even when the film to be measured and the base film are comprised of the insulating films or conductive films whose components are different from each other, a difference in ratio of components of characteristic X-rays between the films can be measured.

Referring to FIGS. 17 and 18, the characteristic X-rays of a silicon (Si) element component are detected even when the thickness of the remaining film is 0.0 nm. This is because the characteristic X-rays of silicon (Si) element are emitted from silicon components diffused into the main conductive film 7A (see FIG. 16). However, since in this embodiment, the presence or absence or the thickness of the remaining film is determined by the ratio of components of the characteristic X-rays, the reduction in accuracy of determination can be suppressed even when the characteristic X-rays of the silicon (Si) element is emitted from the base film. For example, as shown in FIG. 18, for the thickness of the remaining film of 0.0 nm, the ratio of components (Cu/Si) is 80% or more (specifically, 83% or more) at any one of the acceleration voltages. On the other hand, for the thickness of the remaining film of 12.1 nm, the ratio of components (Cu/Si) is less than 80% at any one of the acceleration voltages. Thus, for example, the presence or absence of the remaining film at the bottom of the opening 8 can be checked under control by defining the ratio of components (Cu/Si) of less than 83% as the threshold. For example, taking into consideration variations in depth of the opening 8 over the wafer surface, the control by defining the ratio of components (Cu/Si) of less than 80% as the threshold can estimate the presence of the remaining film in all openings 8 within the wafer surface.

### <Preferred Embodiments of Remaining Film Checking Step>

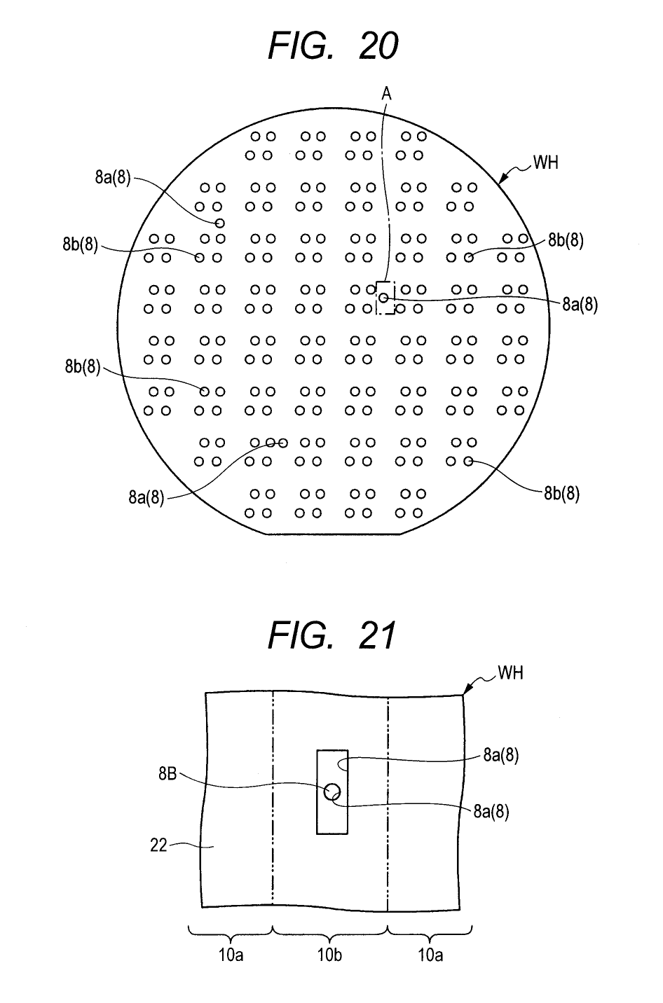

Now, preferred embodiments of the remaining film checking step described above will be described below. FIG. 20 shows a plan view of an example of positions of openings for checking the remaining film in the remaining film checking step shown in FIG. 5. FIG. 21 is an enlarged plan view of a part “A” of FIG. 20. The wafer WH shown in FIG. 20 has a number of openings 8 formed therein. For easy understanding of checking positions, FIG. 20 illustrates only some openings 8, including the openings 8a of interest to be checked, among the openings. A number of openings 8 are formed in each chip region 10a (see FIG. 4) at the wafer WH. In the remaining film checking step, all openings 8 can be detected, which leads to an increase in time for checking, thus reducing the efficiency of manufacturing. However, in this embodiment, some openings 8a among the openings 8 are checked. When the openings 8 are totally formed at the wafer WH, the depth of the openings 8 can be set to substantially the same level by managing the processing time. Thus, as shown in FIG. 20, the presence or absence or the thickness of the remaining films at the openings 8a in arbitrary positions apart from each other (three positions shown in FIG. 20) is determined (evaluated), whereby the presence or absence of the remaining films in other openings 8b to which no electron beam EB (see FIG. 16) is applied can also be estimated. For example, taking into consideration variations in depth of the opening 8 within the surface of the wafer WH, when the thickness of the remaining films in all openings 8a is 10 nm or more, the presence of all remaining films at other openings 8b can be estimated. In this case, the openings 8b are not checked at all, which can greatly shorten the checking time. That is, the remaining film checking step can be performed efficiently.

Although the remaining film checking step of this embodiment involves non-destructive examination, the openings 8b (see FIG. 20) formed in the chip region 10a (see FIG. 4) as a product are not preferably irradiated with the electron beam EB (see FIG. 16) in order to prevent the degradation of electric characteristics of the part around the opening 8 due to the application of the electron beam EB (see FIG. 16). Thus, in this embodiment, as shown in FIG. 21, the openings 8a for checking are formed in the scribing regions 10b disposed between the chip regions 10a in the same process as that in the chip region 10a, and the electron beam EB (see FIG. 16) is applied to the openings 8a. Such a pattern for checking is called a “test elementary group (TEG)”, and by checking the TEG, the state of a pattern formed in the chip region 10a can be estimated. The scribing region 10b is a region which is cut and processed in the separating step shown in FIG. 3. Thus, the TEG pattern is not left in the semiconductor device 1 (see FIG. 1) as the product. For example, even when the electron beam EB (see FIG. 16) is applied to the bottom 8B of each opening 8a for checking formed in the scribing region 10b, the electric characteristics of the product can be prevented from being degraded.

This embodiment has described the example of use of the electron beam EB (see FIG. 16) as the excitation beam for exciting the film to be measured and the base film. However, any other exciting source having an energy necessary for generating the characteristic X-rays can be used instead of the electron beam EB (see FIG. 16). For example, X-rays can be used as the excitation beam. In this case, from the viewpoint of suppressing the increase in noise by applying the excitation beam to the part around the opening 8, preferably, a shielding plate is provided around an irradiation port for the X-rays, and the X-rays are radiated from the opening of the shielding plate. As the excitation beam, the electron beam EB (see FIG. 16) converges more easily than the X-rays. In this embodiment, more specifically, the electron beam EB (see FIG. 16) is used as the excitation beam to irradiate the bottom 8B of the opening 8 having a high aspect ratio, such as a through hole.

### <Application to Contact Layer Formation Step>

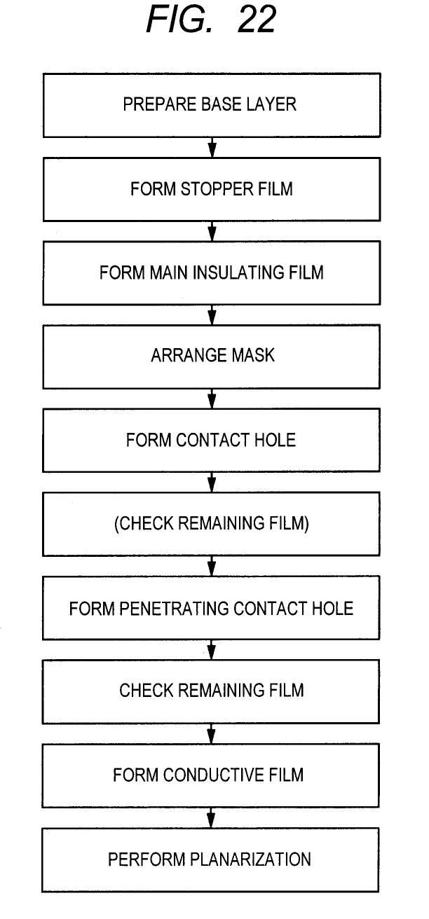

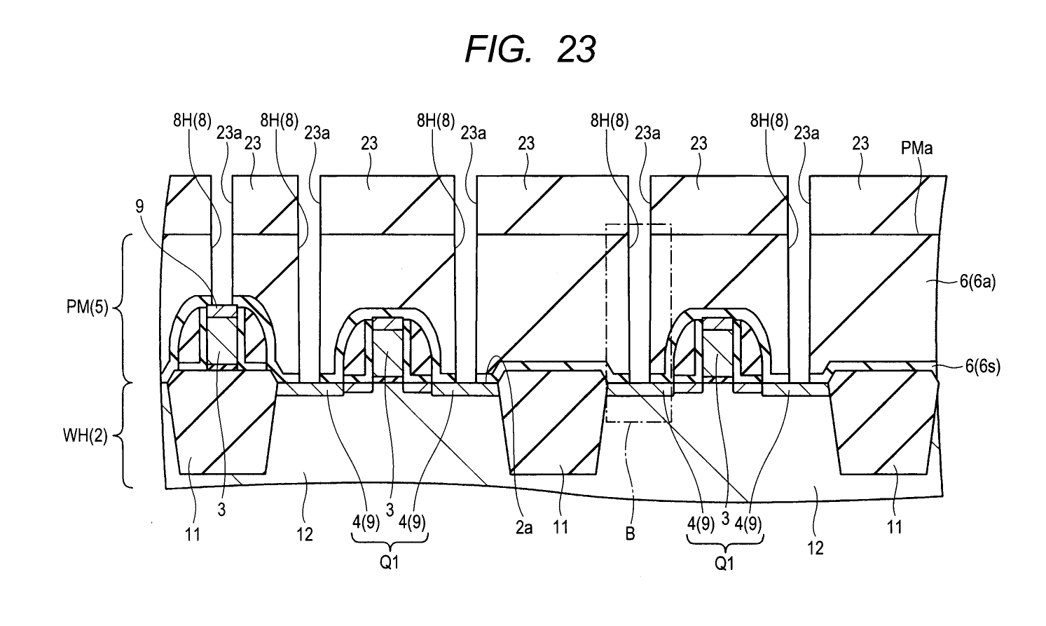

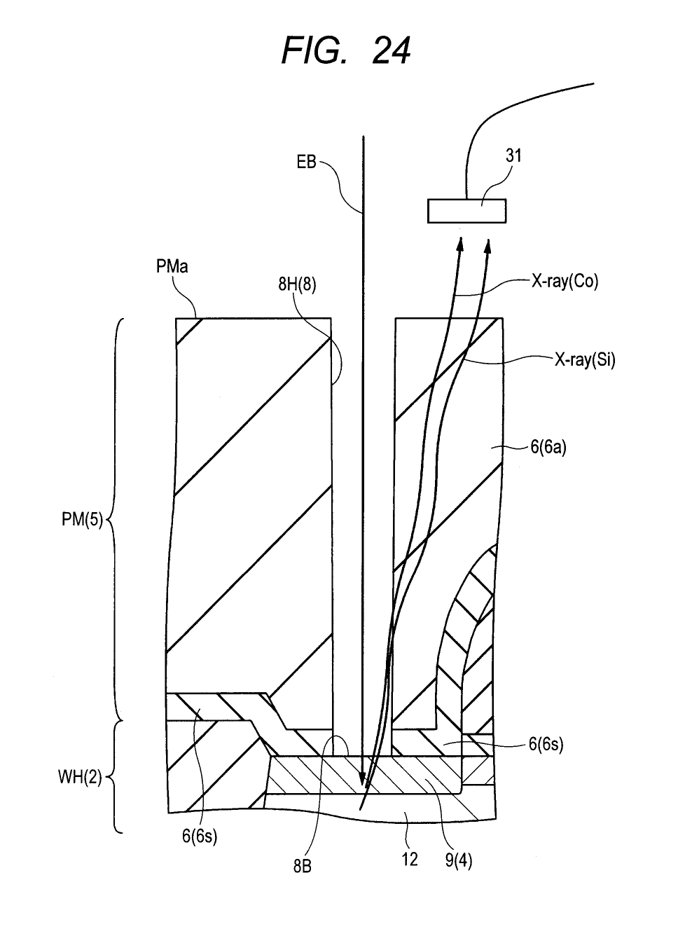

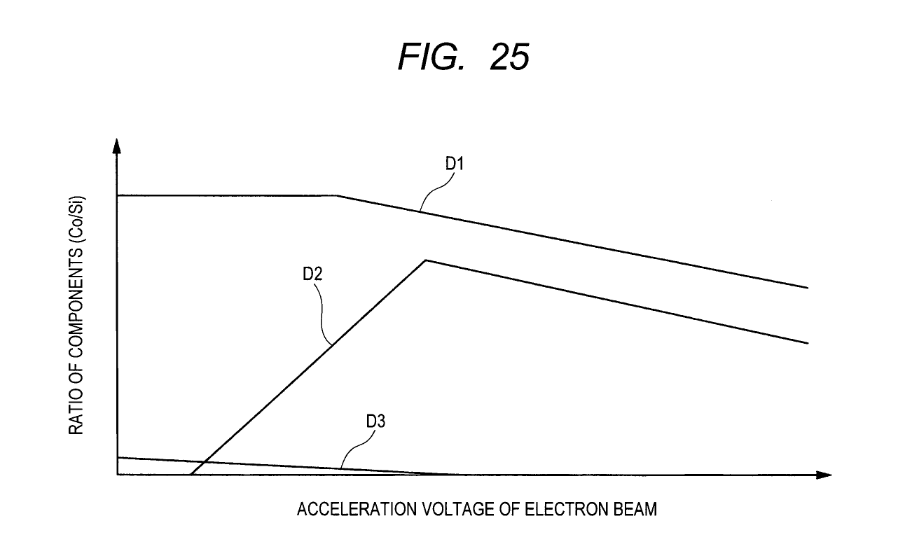

Next, an example in which the above remaining film checking step is applied as a modified example to the contact layer formation step shown in FIG. 3 will be described below. FIG. 22 shows an explanatory diagram of a process flow of the wiring layer lamination step shown in FIG. 3. FIG. 23 shows an enlarged cross-sectional view of the state of completion of a contact hole penetration step shown in FIG. 22. FIG. 24 exemplarily shows an explanatory diagram of the state of a part “B” shown in FIG. 23 after the remaining film checking step. FIG. 25 shows an explanatory diagram of the relationship between the presence or absence of the remaining film and the ratio of components (Co/Si) when changing the intensity (acceleration voltage) of an electron beam applied to the opening shown in FIG. 24. FIGS. 24 and 25 show the example in which a cobalt silicide film is formed as a metal silicide film.

In the contact layer formation step shown in FIG. 3, first, a layer serving as a base layer for the wiring layer is formed as a base layer preparation step. In application to the contact layer formation step, a metal silicide film 9 formed over the surface of the gate electrode 3 and the source and drain regions 4 serves as the base layer. The metal silicide film 9 is formed by forming a metal film, such as a cobalt (Co) film or a nickel (Ni) film, over the surface of the gate electrode 3 and the source and drain regions 4, and by reacting the metal film with silicon by a heat treatment (annealing process) to thereby silicide the metal film. Then, in a stopper film formation step, a stopper insulating film (film to be measured) 6s is deposited (formed). The stopper insulating film 6s is, for example, a silicon nitride film (SN film), and is formed, for example, in a thickness of about 30 nm to 50 nm by the CVD method. In this step, the metal silicide film 9 as the base layer is covered with the stopper insulating film 6s.

Then, in a main insulating film formation step, the insulating film 6a is deposited (formed) as a main interlayer insulating film over the stopper insulating film 6s. The insulating film 6a is formed, for example, by laminating an ozone TEOS (tetra-ethyl-ortho-silicate) film which is a silicon oxide film formed by a thermal CVD method using ozone (O₃) and TEOS, and a plasma TEOS film which is a silicon oxide film formed by a plasma CVD method using the TEOS. Then, in a mask arrangement step, a resist film (not shown) is arranged over the upper surface PMa of the insulating film 6a. Since the metal silicide film 9 on the surface of the gate electrode 3 differs in height from the metal silicide film 9 on the surfaces of the source and drain regions 4 in the contact layer formation step, the respective contact holes 8H have the different heights. In order to suppress the excessive etching in a contact hole formation step, the contact hole 8H above the gate electrode 3 and the contact hole 8H above the source and drain regions 4 are formed using different resist films (masks). Then, in the contact hole formation step, the insulating film 6a is removed from the upper surface PMa side of the insulating film 6a toward the metal silicide film as the base film to thereby form the contact holes (openings, or holes) 8H. A method for removing the insulating film 6a involves performing etching on the film 6a using a resist film (not shown) as an etching mask to form the contact holes 8H. The etching for use can include dry etching, wet etching, and a combination thereof. At this time, like the above wiring layer lamination step, the use of an etching material for the silicon oxide film can suppress the etching from penetrating the stopper insulating film 6s. However, even the use of the etching material for the silicon oxide film also removes the part of the stopper insulating film 6s by etching. The contact hole 8H above the gate electrode 3 and the contact holes 8H above the source and drain regions 4 are formed using the different resist films (masks). For this reason, after forming one of the contact holes 8H, the ashing process or cleaning process is performed to remove the resist film, and then another resist film is arranged so as to form the other contact hole 8H. At this time, a part of the stopper insulating film 6s remains as the remaining film at the bottom of the contact hole 8H, which can suppress the metal silicide film 9 from being contaminated during the ashing process or cleaning process.

Then, in a contact hole penetration step, as shown in FIG. 23, the remaining film of the stopper insulating film 6s under the contact hole 8H is removed. In this step, the remaining film of the stopper insulating film 6s is removed by etching using, as an etching mask, a resist film 23 having through holes 23a formed above the contact holes 8H. Thus, the contact hole 8H penetrates the stopper insulting film 6s in the thickness direction. The metal silicide film 9 as the base film is exposed from the stopper insulating film 6s at the bottom of each contact hole 8H. The metal silicide film 9 is thinner than the conductive film 7 described in the wiring layer lamination step. Since the metal silicide film 9 has a thickness of, for example, several nm to several tens of nm, the etching for a long time will possibly penetrate the metal silicide film 9. In contrast, the lack of the etching time does not penetrate the stopper insulating film 6s, which causes the failure of conduction (open failure). Thus, the technique for accurately controlling the depth of the contact hole 8H is required.

In this embodiment, as shown in FIG. 22, after the contact hole penetration step, the operation proceeds to a remaining film checking step in which the removal of the remaining film and the presence of the metal silicide film 9 are checked. In checking the remaining film of the stopper insulating film 6s shown in FIG. 22, the remaining film checking step of the above-mentioned wiring layer lamination step can be applied. That is, as shown in FIG. 24, for example, the characteristic X-rays emitted by applying the electron beam (excitation beam) EB to the bottom 8B of the contact hole 8H is detected to thereby determine (evaluate) the presence or absence of the stopper insulating film 6s, or the presence or absence of the metal silicide film 9 as a base layer. Specifically, the checking of the remaining film is performed by determining (evaluating) the ratio of element components (Co/Si), that is, the ratio of a metal element component (for example, cobalt) contained in the metal silicide film to a semiconductor element component (for example, silicon) contained in the stopper insulating film 6s as a principal component among the characteristic X-rays of components.

The relationship of the ratio of components (Co/Si) with respect to the change in intensity (acceleration voltage) of the electron beam EB (see FIG. 24) applied to the contact hole will be changed as shown in FIG. 25. When the contact hole 8H penetrates the stopper insulating film 6 and does not penetrate the metal silicide film 9 as the base film as shown in FIG. 23, data D1 changes as described in FIG. 25. That is, the metal silicide film 9 is mainly excited in a region where the acceleration voltage (intensity of the excitation beam) of the electron beam EB (see FIG. 24) is low. This results in an increase in ratio of the characteristic X-ray component derived from a cobalt element to the other component. In contrast, when the acceleration voltage of the electron beam EB (see FIG. 24) is increased, the base layer (well region 12) under the metal silicide film 9 is further excited, which leads to an increase in ratio of the characteristic X-ray component derived from the silicon element to the other component. This results in a decrease in ratio of the components (Co/Si).

When the contact hole 8H shown in FIG. 23 does not penetrate the stopper insulating film 6s and the remaining film of the stopper insulating film 6s remains, data D2 changes as described in FIG. 25. That is, the stopper insulating film 6s is mainly excited in a region where the acceleration voltage (intensity of the excitation beam) of the electron beam EB (see FIG. 24) is low. This results in a decrease in ratio of the characteristic X-ray component derived from a cobalt element to the other component. In contrast, when the acceleration voltage of the electron beam EB (see FIG. 24) is increased, the metal silicide film 9 under the remaining film is further excited, which leads to an increase in ratio of the characteristic X-ray component derived from the cobalt element to the other component. This results in an increase in ratio of the components (Co/Si). When the acceleration voltage of the electron beam EB (see FIG. 24) is further increased, the well region 12 under the metal silicide film 9 is excited, which leads to an increase in ratio of the characteristic X-ray component derived from the silicon element to the other component. This results in a decrease in ratio of the components (Co/Si).

When the contact hole 8H shown in FIG. 23 penetrates the metal silicide film 9 as the base film, data D3 changes as described in FIG. 25. That is, in a region where the acceleration voltage (intensity of the excitation beam) of the electron beam EB (see FIG. 24) is low, the characteristic X-rays derived from the cobalt element except for the cobalt element slightly diffused into the well region 12 are hardly detected. Even when the acceleration voltage of the electron beam EB (see FIG. 24) is increased, the amount of cobalt components is not increased, so that the ratio of components (Co/Si) is still low regardless of the acceleration voltage of the electron beam EB (see FIG. 24). In other words, the measurement is performed while the metal silicide film 9 is set as the film to be measured, and the well region 12 is set as the base film.

The presence or absence of the stopper insulating film 6s, or the presence or absence of the metal silicide film 9 as the base layer can be easily determined (evaluated) from the correlation between the ratio of components (Co/Si) and the acceleration voltage (intensity of the excitation beam) of the electron beam EB (see FIG. 24) shown in FIG. 25. That is, for example, when the electron beam EB (see FIG. 24) (an excitation beam having a low intensity) is applied at a low acceleration voltage of, for example, about 1 kV to 2 kV, the ratio of components (Co/Si) of the data D2 and D3 is much smaller than that of the data D1. Thus, when the ratio of components (Co/Si) is lower than the threshold, either the failure of removal of the stopper insulating film 6s or the failure of penetration of the metal silicide film 9 is determined to be caused. At this time, the result of the determination is feedbacked to the manufacturing process, which can prevent the loss of products due to mass production of defective products. For example, the data D2 and the data D3 can be classified by radiating the electron beam EB (see FIG. 24) at an acceleration voltage, for example, of about 2 kV to 4 kV. That is, since the contents of the failures can be recognized, the causes for occurrence of the failures are easily specified. In applying the remaining film checking step to the contact layer formation step, the above checking device 30 shown in FIG. 19 can also be used, and thus a redundant description thereof will be omitted below.

In this way, according to this embodiment, the remaining film checking step can be applied as means for checking not only the presence of the remaining film, but also the absence of the remaining film, and the etching not penetrating the base film, as described in the wiring layer lamination step. In the example of this embodiment, the checking step is applied to a checking process for confirming the presence of the remaining film in the wiring layer lamination step. Further, in other examples, the checking step is applied to a checking process for confirming the absence of the remaining film, or a checking process for confirming the etching not penetrating the base film in the contact layer formation step. These steps, however, can be applied in combination. For example, after the contact hole penetration step shown in FIG. 5, the remaining film checking step can be applied to a checking process for confirming the absence of the remaining film, or a checking process for confirming the etching not penetrating the base layer. For example, the remaining film checking step can be applied as a checking process for confirming the presence of the remaining film between the contact hole formation step shown in FIG. 22 and the contact hole penetration step.

Then, in a conductive film formation step shown in FIG. 22, a conductive film is embedded in each contact hole 8H to form the plug 7a shown in FIG. 2.

In this step, first, for example, a titanium film and a titanium nitride film are sequentially deposited as a barrier conductive film over the upper surface PMa of the insulating film 6a (see FIG. 23) and the inner surface of each contact hole 8H. The barrier conductive film can be formed, for example, by a metal CVD process using TiCl₄ as a metal source gas. As the method of forming a barrier conductive film, in addition to the meal CVD method, sputtering deposition, and a combination of the metal CVD method and the sputtering deposition can be applied as long as no problems about covering or the like occur. Then, a tungsten film is formed as a main conductive film over the barrier conductive film in each contact hole 8H. The tungsten film is formed to fill the contact holes 8H by the metal CVD process using, for example, WF₆ as a metal source gas. Then, in a planarization step, the planarization process is performed by the metal CMP to remove the tungsten film and the barrier conductive film outside the contact holes 8H. In the above steps, as shown in FIG. 2, the wiring layer PM as a contact layer is formed over the upper surface of a pre-metal interlayer insulating film. A plug 7a is exposed at the wiring layer PM and electrically coupled to the gate electrode 3 or the source and drain regions 4. The wiring layer PM serves as a base layer when forming the wiring layer M1. In the wiring layer lamination step shown in FIG. 3, a plurality of wiring layers 5 are laminated over the wiring layer PM.

### Modified Example

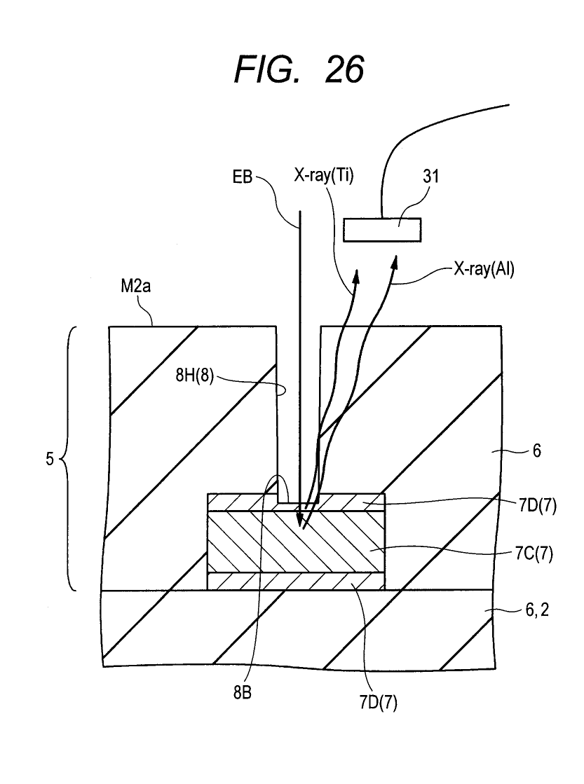

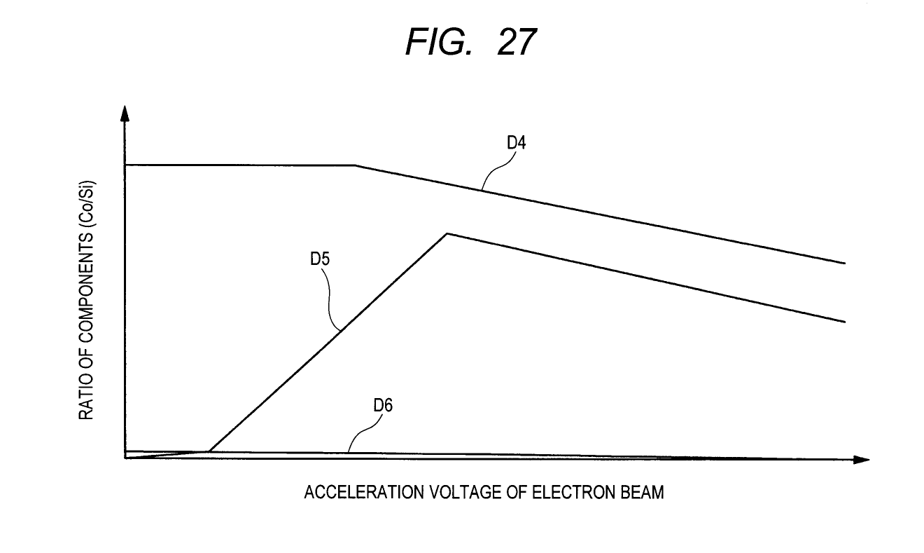

Next, a modified example of this embodiment will be described below. In the wiring layer formation step and the contact layer formation step, the stopper insulating film 6s is a film to be measured, and the conductive film 7 or the metal silicide film 9 serves as a base film by way of example. The combination of the film to be measured and the base film in the remaining film checking step of this embodiment is not limited to the above one. For example, even when the film to be measured and the base film are conductive films, or even when the film to be measured and the base film are insulating films, the invention can be applied to any other film to be measured and any other base film from which characteristic X-rays from different element components can be obtained. This modified example will describe the case where the film to be measured and the base film are conductive films by way of example. FIG. 26 is an explanatory diagram exemplarily showing a modified example of the remaining film checking step shown in FIG. 16. FIG. 27 is an explanatory diagram showing the relationship between the presence or absence of the remaining film and a ratio of components (Ti/Al) when changing the intensity (acceleration voltage) of an electron beam applied to the opening shown in FIG. 26.

In a wiring layer 5 shown in FIG. 26, barrier conductive films 7D thinner than the main conductive film 7C are deposited of, for example, titanium nitride (TiN) on the respective upper and lower surfaces of a main conductive film 7C formed of, for example, aluminum (Al) to thereby form a conductive film 7. An insulating film 6 is laminated over the conductive film 7, and a contact hole 8H is formed from the upper surface of the insulating film 6 toward the conductive film 7. An interlayer conductive path for electrically coupling the wiring layer 5 with a wiring layer laminated over the wiring layer 5 is formed by filling the contact hole 8H with a conductive film (not shown) to serve as a plug. Thus, in a step of forming the contact hole 8H, it is necessary to surely expose the conductive film 7 at the bottom 8B of the contact hole 8H. On the other hand, if the contact hole 8H penetrates the barrier conductive film 7D, the main conductive film 7C will be exposed. For this reason, a part of the barrier conductive film 7D is required to remain at the bottom 8B of the contact hole 8H.

Since the conductive film 7 is surely exposed with the part of the thin barrier conductive film 7D remaining, the above-mentioned remaining film checking step can be applied. Specifically, after forming the contact hole 8H, the remaining film checking step is applied by setting the barrier conductive film 7D as the film to be measured and the main conductive film 7C as the base film. For example, the determination (evaluation) is performed by the ratio (Ti/Al) of a metal element (for example, titanium) component contained in the barrier conductive film 7D as a principal component to that of a metal element (for example, aluminum) component contained in the main conductive film 7C as a principal component among the characteristic X-rays of the components.

The relationship between the ratio of components (Ti/Al) and the change in intensity (acceleration voltage) of the electron beam EB (see FIG. 26) applied to the contact holes changes as shown in FIG. 27. First, when the contact hole 8H penetrates the insulating film 6 and does not penetrate the barrier conductive film 7D as shown in FIG. 26, data D4 changes as described in FIG. 27. That is, the barrier conductive film 7D is mainly excited in a region where the acceleration voltage (intensity of the excitation beam) of the electron beam EB (see FIG. 26) is low. The ratio of the characteristic X-ray component derived from a titanium element to the other component becomes high. In contrast, when the acceleration voltage of the electron beam EB (see FIG. 26) is increased, the main conductive film 7C under the barrier conductive film 7D is excited, which leads to an increase in ratio of the characteristic X-ray component derived from the aluminum element to the other component. This results in a decrease in ratio of components (Ti/Al).

First, when the contact hole 8H shown in FIG. 26 does not penetrate the insulating film 6 and the barrier conductive film 7D is not exposed, data D5 changes as described in FIG. 27. That is, the insulating film 6 is mainly excited in a region where the acceleration voltage (intensity of the excitation beam) of the electron beam EB (see FIG. 26) is very low. Thus, the characteristic X-rays derived from the titanium element or aluminum element are hardly detected. In contrast, when the acceleration voltage of the electron beam EB (see FIG. 26) is increased, the ratio of the characteristic X-ray component derived from the titanium element to the other component is increased, which results in an increase in ratio of components (Ti/Al). In contrast, when the acceleration voltage of the electron beam EB (see FIG. 26) is further increased, the main conductive film 7C as the base layer of the barrier conductive film 7D is excited, which leads to an increase in ratio of the characteristic X-ray component derived from the aluminum element to the other component. This results in a decrease in ratio of components (Ti/Al).

First, when the contact hole 8H shown in FIG. 26 penetrates the barrier conductive film 7D, data D6 changes as described in FIG. 27. That is, the characteristic X-rays derived from the titanium element are hardly detected regardless of the acceleration voltage of the electron beam EB (see FIG. 26). Thus, the ratio of components (Ti/Al) is low regardless of the acceleration voltage of the electron beam EB (see FIG. 26).

The presence or absence of the remaining film of the insulating film 6, or the presence or absence of the barrier conductive film 7D can be easily determined (evaluated) from the correlation between the ratio of components (Ti/Al) and the acceleration voltage (intensity of the excitation beam) of the electron beam EB (see FIG. 26) as shown in FIG. 27. That is, for example, when the electron beam EB (see FIG. 26) (an excitation beam having a low intensity) is applied at a low acceleration voltage of, for example, about 1 kV to 2 kV, the ratio of components (Ti/Al) of the data D5 and D6 is much smaller than that of the data D4. When the ratio of components (Ti/Al) is lower than the threshold, either the failure of removal of the insulating film 6 or the failure of penetration of the barrier conductive film 7D is found to occur. At this time, the result of the determination is feedbacked to the manufacturing process, which can prevent the loss of products due to mass production of defective products. For example, the data D5 and the data D6 can be classified by radiating the electron beam EB (see FIG. 26) at an acceleration voltage, for example, of about 2 kV to 4 kV. When the remaining film checking step is applied to the contact layer formation step, the checking device 30 shown in FIG. 19 can also be used, and thus a redundant description thereof will be omitted below.

In this way, according to this modified example, the use of the system for detecting the characteristic X-rays can easily measure the presence or absence or the thickness of the remaining film even when the film to be measured and the base film are comprised of the conductive films.

The invention made by the inventors have been specifically described based on the embodiments, but is not limited to the disclosed embodiments. It is apparent that various modifications can be made to the embodiments without departing from the scope of the invention.

For example, the above embodiments have described the method for measuring the presence or absence or the thickness of the remaining film by previously obtaining the data for determination, and then comparing the measurement data on the ratio of components with the data for determination. However, even when the data for determination is not prepared previously, the presence or absence of the remaining film can be determined. For example, as shown in FIGS. 17, 25, and 27, the presence or absence of the remaining film can be determined without comparing to the data for determination, only by applying the excitation beam having such an intensity that largely changes the data on ratio of components of the characteristic X-rays according to the presence or absence of the remaining film (for example, the electron beam having an acceleration voltage of about 1 kV to 2 kV).

For example, although the modified example has described the determination of the presence or absence of the barrier conductive film 7D as the film to be measured, the invention can also determine the thickness of the barrier conductive film 7D as described about the above wiring layer lamination step.

The present invention can be used for semiconductor devices including wiring layers laminated over a semiconductor substrate.

What is claimed is:

1. A manufacturing method of a semiconductor device, comprising the steps of:
(a) laminating a base film and a film to be measured above the base film, over a main surface of a semiconductor substrate;
(b) forming an opening in the film to be measured;
(c) applying an excitation beam to a bottom of the opening to emit characteristic X-rays; and
(d) detecting the characteristic X-rays to thereby determine the presence or absence of the film to be measured at the bottom of the opening based on a result of the detection of the characteristic X-rays.

2. The manufacturing method of a semiconductor device according to claim 1,
wherein the characteristic X-rays emitted in the step (c) contains a first element component derived from a first element forming the film to be measured, and a second element component derived from a second element forming the base film, and
wherein in the step (d), the presence or absence of the film to be measured is determined by a ratio of the first element component to the second element component of the characteristic X-rays.

3. The manufacturing method of a semiconductor device according to claim 2, further comprising, before the step (c), a step of obtaining data for determination by measuring a correlation between an intensity of the excitation beam and the ratio of components,
wherein in the step (d), the presence or absence of the film to be measured is determined by comparing measurement data about the ratio of the first element component to the second element component with the data for determination.

4. The manufacturing method of a semiconductor device according to claim 3,
wherein in the step (b), a plurality of the openings are formed over the main surface of the semiconductor substrate, and
wherein in the step (c), the excitation beam is applied to one or more first openings among the openings while no excitation beam is applied to a second opening other than the first opening among the openings.

5. The manufacturing method of a semiconductor device according to claim 4,
wherein the semiconductor substrate has a plurality of chip regions and scribing regions disposed between the chip regions over the main surface, and
wherein the one or more first openings are formed in the scribing regions, and the second openings are formed in the chip regions.

6. The manufacturing method of a semiconductor device according to claim 1, wherein the excitation beam is an electron beam.

7. The manufacturing method of a semiconductor device according to claim 1, wherein the opening is a contact hole serving as a conductive route for electrically coupling a lower layer wiring to an upper layer wiring.

8. The manufacturing method of a semiconductor device according to claim 1, wherein the film to be measured is a conductive film containing a first element, and the base film is a conductive film containing a second element other than the first element.

9. The manufacturing method of a semiconductor device according to claim 1, wherein the film to be measured is an insulating film containing a first element, and the base film is a conductive film containing a second element other than the first element.

10. The manufacturing method of a semiconductor device according to claim 1, wherein in the step (b), the opening is formed by etching using a resist film disposed over the film to be measured as a mask,
said manufacturing method further comprising, after confirming the presence of the film to be measured in the step (d), a step of:
(e) removing the resist film.

11. The manufacturing method of a semiconductor device according to claim 1, further comprising, after removing the film to be measured and checking the base film exposed at the bottom of the opening in the step (d), the step of:
(e) forming a conductive film in the opening.

12. The manufacturing method of a semiconductor device according to claim 11, wherein in the step (d), the opening not penetrating the base film is further checked.

13. A manufacturing method of a semiconductor device, comprising the steps of:
(a) laminating a base film and a film to be measured above the base film, over a main surface of a semiconductor substrate;
(b) forming an opening in the film to be measured;
(c) applying an excitation beam to a bottom of the opening to emit characteristic X-rays; and
(d) detecting the characteristic X-rays to thereby determine the thickness of the film to be measured at the bottom of the opening based on a result of the detection of the characteristic X-rays,
wherein the characteristic X-rays emitted in the step (c) contains a first element component derived from a first element forming the film to be measured, and a second element component derived from a second element forming the base film, and
wherein said manufacturing method further comprises, before the step (c), a step of obtaining data for determination by measuring a correlation between an intensity of the excitation beam and the ratio of the first element component to the second element component,
wherein in the step (d), the thickness of the film to be measured is determined by comparing measurement data about the ratio of the first element component to the second element component with the data for determination.

14. The manufacturing method of a semiconductor device according to claim 13,
wherein in the step (b), a plurality of the openings are formed over the main surface of the semiconductor substrate, and
wherein in the step (c), the excitation beam is applied to one or more first openings among the openings while no excitation beam is applied to a second opening other than the first opening among the openings.

15. The manufacturing method of a semiconductor device according to claim 14,
wherein the semiconductor substrate has a plurality of chip regions and scribing regions disposed between the chip regions over the main surface of the semiconductor substrate, and
wherein the one or more first openings are formed in the scribing regions, and the second openings are formed in the chip regions.

16. The manufacturing method of a semiconductor device according to claim 13, wherein the film to be measured is a conductive film containing the first element, and the base film is a conductive film containing a second element other than the first element.

17. The manufacturing method of a semiconductor device according to claim 13, wherein the film to be measured is an insulating film containing a first element, and the base film is a conductive film containing a second element other than the first element.

18. The manufacturing method of a semiconductor device according to claim 13, wherein in the step (b), the opening is formed by etching using a resist film disposed over the film to be measured as a mask,
said manufacturing method further comprising, after confirming the presence of the film to be measured in the step (d), a step of:
(e) removing the resist film.

19. The manufacturing method of a semiconductor device according to claim 13, further comprising, after removing the film to be measured and checking the base film exposed at the bottom of the opening in the step (d), a step of:
(e) forming a conductive film in the opening.

20. The manufacturing method of a semiconductor device according to claim 13, wherein in the step (d), the opening not penetrating the base film is further checked.
